(19) United States
(12) Patent Application Publication
(10) Pub. No.: US 2011/0291708 A1
(43) Pub. Date: Dec. 1, 2011

(54) ELECTRONIC APPARATUS AND METHOD OF DRIVING THE SAME

(75) Inventor: Tokuro OZAWA, Suwa (JP)

(73) Assignee: SEIKO EPSON CORPORATION, Tokyo (JP)

(21) Appl. No.: 13/115,443

(22) Filed: May 25, 2011

(30) Foreign Application Priority Data
May 26, 2010 (JP) 2010-120195

(51) Int. Cl. H03B 1/00

(52) U.S. Cl. 327/108

(57) ABSTRACT

An electronic apparatus includes an electronic circuit including a driving transistor, an additional capacitive element and a first switch for controlling a connection between a circuit point and a control terminal and a driving circuit which controls the first switch to an off state and changes the potential of the control terminal such that the driving transistor transitions to an on state in a first period, controls the first switch to the on state so as to set the potential of the control terminal to an initial compensation value, in a second period, and controls the first switch to the on state and changes the driving potential from the first potential to the second potential such that the driving transistor transitions to the on state, in a third period.

### CROSS-REFERENCE TO RELATED APPLICATION

This application is based on and claims priority from Japanese Patent Application No. 2010-120195, filed on May 26, 2010, the contents of which are incorporated herein by reference.

### BACKGROUND

1. Technical Field

The present invention relates to a technique of compensating for error of characteristics (more particularly, threshold voltage) of a transistor within an electronic circuit.

2. Related Art

In JP-A-2009-48202, a technique of compensating for error of characteristics (threshold voltage or mobility) of a driving transistor used for driving an organic EL element is disclosed. FIG. 43 is a circuit diagram of a pixel circuit 90 disclosed in JP-A-2009-48202 (FIG. 11). In a write period in which a gradation potential according to a designated gradation is supplied to an electrode 93 of a capacitive element 92 through a switch 91, a gate and a drain are connected (diode-connected) to a switch 95 in a state in which a driving transistor 94 is held in an on state. Accordingly, a voltage between the gate and the source of the driving transistor 94 is set to a voltage Vrst for compensating for error of its threshold voltage VTH. A driving potential having a triangular wave shape is supplied to the electrode 93 of the pixel circuit 90 in a driving period after the elapse of the write period so as to variably control a light emission time of a light emitting element 97 connected to a circuit point 96 according to the designated gradation.

However, it is difficult to apply the technique of JP-A-2009-48202 to a configuration in which an electro-optical element having high resistance, such as an electrophoretic element or a liquid crystal element, is connected to the circuit point 96. Since current barely flows in the electro-optical element, the potential of the circuit point 96 is not set. Accordingly, even when the driving transistor 94 and the switch 95 are controlled to the on state in the write period, the voltage between the gate and the source of the driving transistor 94 does not converge to a target voltage Vrst.

### SUMMARY

An advantage of some aspects of the invention is that it efficiently compensates for error of characteristics of a driving transistor.

According to an aspect of the invention, there is provided an electronic apparatus including an electronic circuit and a driving circuit, wherein the electronic circuit includes a driving transistor including a first terminal connected to a driving potential line to which a driving potential is supplied, a second terminal connected to a circuit point, and a control terminal for controlling a connection state between both terminals; an additional capacitive element connected to the circuit point; and a first switch (for example, a switch S_{W1}) which controls a connection between the circuit point and the control terminal, wherein the driving circuit controls the first switch to an off state and changes the potential of the control terminal such that the driving transistor transitions to an on state, in a first period (for example, an initialization period T_{RST}) in which the driving potential is set to a first potential (for example, a high-level potential V_{DR}_{_{—}}_{H}), controls the first switch to the on state so as to set the potential of the control terminal to an initial compensation value, in a second period (for example, a compensation preparation period Q_{A}) after the elapse of the first period, and controls the first switch to the on state and changes the driving potential from the first potential to a second potential (for example, a low-level potential V_{DR}_{_{—}}_{L}) such that the driving transistor transitions to the on state, in a third period (for example, a compensation execution period Q_{B}) after the elapse of the second period.

In the above configuration, in the first period, the first potential is supplied from the driving potential line to the circuit point through the first terminal and the second terminal of the driving transistor controlled to the on state according to the change in the potential of the control terminal. In the second period, the first switch is controlled to the on state and the additional capacitive element is connected to the control terminal such that the potential of the control terminal is set to the initial compensation value. In the third period, since the driving transistor diode-connected through the first switch is controlled to the on state according to the change in the driving potential (the potential of the first terminal), the charges of the control terminal are moved to the driving potential line through the first switch, the circuit point, the second terminal and the first terminal. Accordingly, the voltage between the control terminal of the driving transistor and the first terminal approaches (ideally, reaches) its threshold voltage. In the above configuration, since the potential of the circuit point is set to the first potential in the first period, if the first potential is appropriately selected, current may reliably flow in the driving transistor in the third period. Accordingly, even in a state in which a driven element with high resistance is connected to the circuit point, it is possible to effectively compensate for the error of the characteristics of the driving transistor by the compensation operation of the third period.

In the second period, the method of setting the potential of the control terminal to the initial compensation value is arbitrary. For example, the driving circuit associated with the aspect of the invention may change the potential of the control terminal in an opposite direction of the change in the first period before the start of the second period and controls the first switch to the on state in the second period so as to set the potential of the control terminal to the initial compensation value. In the aspect of the invention, if the potential of the control terminal is changed in the opposite direction of the change in the first period before the start of the second period and the additional capacitive element and the control terminal are connected through the first switch in the second period, charge is moved between the additional capacitive element and the control terminal such that the initial compensation value is set. Accordingly, it is possible to set the initial compensation value (for example, set the initial compensation value to a high potential if the driving transistor is of an N channel type) such that the driving transistor easily transitions to the on state in the third period.

The driving circuit associated with the aspect of the invention may change the potential of the control terminal in an opposite direction of the change in the first period so as to set the potential of the control terminal to the initial compensation value, after the first switch is controlled to the on state, in the second period. In the aspect of the invention, while the first switch is controlled to the off state in the first period such that the additional capacitive element is insulated from the control terminal in the first period, the first switch is controlled to the on state in the second period such that the additional capacitive element is connected to the control terminal. Accordingly, the amount of change in the potential of the control terminal in the second period is less than the amount of change in the first period. Using the above-described difference, it is possible to set the initial compensation value (for example, set the initial compensation value to a high potential if the driving transistor is of an N channel type) such that the driving transistor easily transitions to the on state in the third period.

According to the configuration in which the initial compensation value is set such that the driving transistor easily transitions to the on state in the third period as in the above-described aspects of the invention, it is possible to reduce the amplitude (a difference between the first potential and the second potential) of the driving potential necessary to change the driving transistor to the on state in the third period.

In the aspect of the invention, the electronic circuit may include a first capacitive element including a first electrode (for example, an electrode E₁) and a second electrode (for example, an electrode E₂), the second electrode may be connected to the control terminal, and the driving circuit may supply a signal potential (for example, a gradation potential V_{D[m,n]}) to the first electrode within the third period or after the elapse of the third period, and variably sets a voltage between the control terminal and the first terminal in a fourth period (for example, an operation period T_{DRV}) after the elapse of the third period. In the above aspect, the state (on/off) of the driving transistor is controlled according to the level of the absolute value of the voltage between the control terminal and the first terminal set in the fourth period and the absolute value of the voltage set according to the signal potential supplied to the first electrode and the compensation operation in the third period. That is, the electronic circuit functions as a comparison circuit for generating a voltage signal in the circuit point according to the result of comparing the voltage between the control terminal and the first terminal within the fourth period and before the start of the fourth period.

The driving circuit of a suitable configuration of the aspect of the invention may variably set the potential of the first electrode in the fourth period. In the configuration of the invention, the potential of the control terminal of the driving transistor is in tandem with the potential of the first electrode such that the voltage between the control terminal and the first terminal is variably set. The electronic circuit of another configuration of the aspect of the invention may include a second capacitive element including a third electrode (for example, an electrode E₃) and a fourth electrode (for example, an electrode E₄), the fourth electrode may be connected to the control terminal, and the driving circuit may variably set the potential of the third electrode in the fourth period. In the configuration of the aspect of the invention, the potential of the control terminal of the driving transistor is in tandem with the potential of the third electrode such that the voltage between the control terminal and the first terminal is variably set. According to the configuration of the aspect of the invention, it is possible to reduce the amplitude of the potential of the first electrode as compared to the configuration of the aspect of the invention. According to the configuration of the aspect of the invention, the second capacitive element of the configuration of the aspect of the invention is unnecessary. The driving circuit of another suitable configuration of the aspect of the invention may variably set the driving potential of the driving potential line in the fourth period. In the configuration of the invention, the voltage between the control terminal and the first terminal may be variably set according to the driving potential.

The configuration of the electronic circuit is appropriately changed. For example, in the electronic circuit associated with an aspect of the invention, the first electrode of the first capacitive element may be directly connected to a signal line to which the signal potential is supplied. The electronic circuit associated with an aspect of the invention may include a second switch (for example, a switch S_{W2}) which controls electrical connection between the first electrode of the first capacitive element and a signal line to which the signal potential is supplied. According to the aspect of the invention, it is possible to reduce the number of active elements (switches) as compared to the aspect of the invention. In the aspect of the invention, since the second switch is controlled to the off state such that the first electrode is electrically insulated from the signal line, it is possible to reduce the capacitive component pertaining to the signal line as compared to the aspect of the invention.

A suitable example of an electronic apparatus according to the above aspects is an electro-optical device for driving an electro-optical element. The electro-optical device includes an electro-optical element connected to a circuit point of an electronic circuit of the electronic apparatus associated with the above aspects. The electro-optical element is a driven element for converting one to the other of an electrical operation (electric field application or current supply) and an optical operation (gradation or luminance change). The electro-optical device may be mounted in various electronic apparatus as a display apparatus for displaying an image. The electro-optical device of the invention is suitably employed in an electronic apparatus such as a portable information terminal or an electronic paper.

The invention specifies a method of driving the electronic apparatus associated with the above aspects. More specifically, there is provided a method of driving an electronic apparatus including a driving transistor having a first terminal connected to a driving potential line to which a driving potential is supplied, a second terminal connected to a circuit point and a control terminal for controlling a connection state between both terminals, an additional capacitive element connected to the circuit point, and a first switch which controls a connection between the circuit point and the control terminal, the method including: controlling the first switch to an off state and changing the potential of the control terminal such that the driving transistor transitions to an on state, in a first period in which the driving potential is set to a first potential; controlling the first switch to the on state so as to set the potential of the control terminal to an initial compensation value, in a second period after the elapse of the first period; and controlling the first switch to the on state and changing the driving potential from the first potential to a second potential such that the driving transistor transitions to the on state, in a third period after the elapse of the second period. According to the above driving method, the same operations and effects as the electronic apparatus according to the invention are realized.

### BRIEF DESCRIPTION OF THE DRAWINGS

The invention will be described with reference to the accompanying drawings, wherein like numbers reference like elements.

FIG. 1 is a block diagram of an electro-optical device according to a first embodiment.

FIG. 2 is a circuit diagram of a pixel circuit of the first embodiment.

FIG. 3 is a schematic diagram of an electrophoretic element.

FIG. 4 is an explanatory diagram of an operation of the first embodiment.

FIG. 5 is an explanatory diagram of an operation of an initialization period and a compensation period of the first embodiment.

FIG. 6 is an explanatory diagram of a pixel circuit of the initialization period of the first embodiment.

FIG. 7 is an explanatory diagram of the pixel circuit of an end point of the initialization period of the first embodiment.

FIG. 8 is an explanatory diagram of the pixel circuit of a compensation preparation period (during a writing operation) of the first embodiment.

FIG. 9 is an explanatory diagram of the pixel circuit of a compensation preparation period (during setting of an initial compensation value) of the first embodiment.

FIG. 10 is an explanatory diagram of the pixel circuit of a compensation execution period of the first embodiment.

FIG. 11 is an explanatory diagram of the pixel circuit of an end point of the compensation execution period of the first embodiment.

FIG. 12 is an explanatory diagram of the pixel circuit of an operation period of the first embodiment.

FIG. 13 is an explanatory diagram of a relationship between a driving time of a driving transistor and a gradation potential of the first embodiment.

FIG. 14 is a graph of the gradation potential and the amount of charge passing through the driving transistor of the first embodiment.

FIG. 15 is an explanatory diagram of an operation of a second embodiment.

FIG. 16 is an explanatory diagram of a potential of a gate of a driving transistor of the second embodiment.

FIG. 17 is a circuit diagram of a pixel circuit of a third embodiment.

FIG. 18 is an explanatory diagram of an operation of the third embodiment.

FIG. 19 is an explanatory diagram of an operation of a fourth embodiment.

FIG. 20 is an explanatory diagram of a relationship between an operation time of a driving transistor and a gradation potential of the fourth embodiment.

FIG. 21 is a block diagram of an electro-optical device according to a fifth embodiment.

FIG. 22 is a circuit diagram of a pixel circuit of the fifth embodiment.

FIG. 23 is an explanatory diagram of an operation of the fifth embodiment.

FIG. 24 is an explanatory diagram of an initialization period and a compensation period of the fifth embodiment.

FIG. 25 is an explanatory diagram of a write period and an operation period of the fifth embodiment.

FIG. 26 is an explanatory diagram of the pixel circuit of the initialization period of the fifth embodiment.

FIG. 27 is an explanatory diagram of the pixel circuit of a compensation preparation period (first half) of the fifth embodiment.

FIG. 28 is an explanatory diagram of the pixel circuit of a compensation preparation period (second half) of the fifth embodiment.

FIG. 29 is an explanatory diagram of the pixel circuit of a compensation execution period of the fifth embodiment.

FIG. 30 is an explanatory diagram of the pixel circuit of an end point of the compensation execution period of the fifth embodiment.

FIG. 31 is an explanatory diagram of the pixel circuit of a write period of the fifth embodiment.

FIG. 32 is an explanatory diagram of the pixel circuit of an operation period of the fifth embodiment.

FIG. 33 is an explanatory diagram of a relationship between a driving time of a driving transistor and a gradation potential of the fifth embodiment.

FIG. 34 is a graph of the gradation potential and the amount of charge passing through the driving transistor of the fifth embodiment.

FIG. 35 is an explanatory diagram of an operation of a sixth embodiment.

FIG. 36 is an explanatory diagram of an operation of an initialization period and a compensation period of the sixth embodiment.

FIG. 37 is an explanatory diagram of an operation of a seventh embodiment.

FIG. 38 is an explanatory diagram of a relationship between driving of a driving transistor and visibility of a display image.

FIG. 39 is a circuit diagram of a pixel circuit according to a modified example.

FIG. 40 is a circuit diagram of a pixel circuit according to a modified example.

FIG. 41 is a perspective view of an electronic apparatus (information terminal).

FIG. 42 is a perspective view of an electronic apparatus (electronic paper).

FIG. 43 is a circuit diagram of a pixel circuit of JP-A-2009-48202.

### DESCRIPTION OF EXEMPLARY EMBODIMENTS

### A: First Embodiment

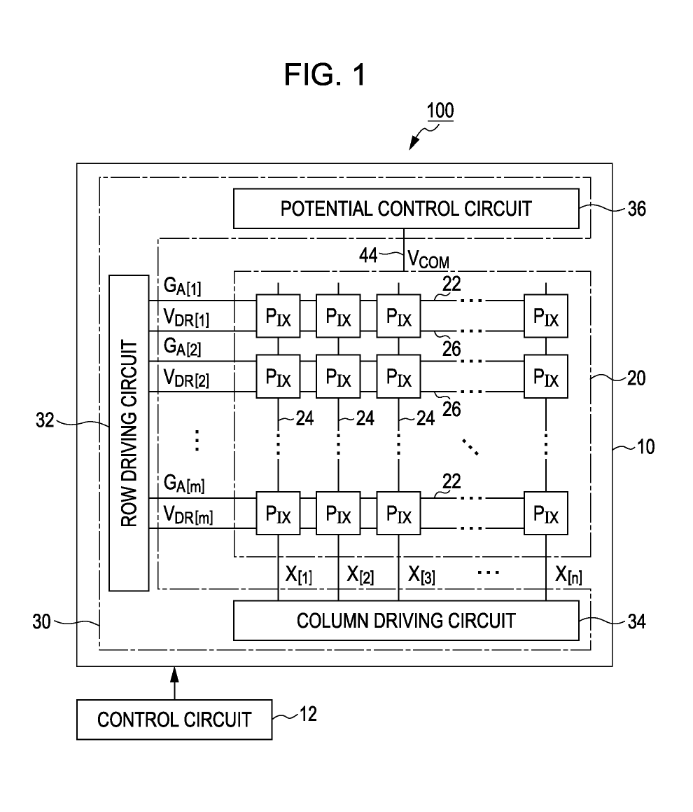

FIG. 1 is a block diagram of an electro-optical device 100 according to a first embodiment. The electro-optical device 100 is an electrophoretic display device for displaying an image utilizing electrophoresis of charged particles and includes a display panel 10 and a control circuit 12 as shown in FIG. 1. The display panel 10 includes a display unit 20 in which a plurality of pixel circuits P_{IX} is arranged on a plane and a driving circuit 30 for driving each pixel circuit P_{IX}. The control circuit 12 controls the display panel 10 (driving circuit 30) so as to display an image on the display unit 20.

In the display unit 20, M control lines 22 and N signal lines 24 are formed so as to intersect each other (M and N are natural integers). The plurality of pixel circuits P_{IX} in the display unit 20 is arranged at positions corresponding to the intersection between the control lines 22 and the signal lines 24 in an M×N matrix. In the display unit 20, M driving potential lines 26 are formed in parallel to the control lines 22.

The driving circuit 30 drives the pixel circuits P_{IX} under the control of the control circuit 12. As shown in FIG. 1, the driving circuit 30 includes a row driving circuit 32, a column driving circuit 34, and a potential control circuit 36. The row driving circuit 32 supplies control signals G_{A[1]} to G_{A[m]} to the control lines 22 and supplies driving potentials V_{DR[1]} to V_{DR[m]} to the driving potential lines 26. Each of the driving potentials V_{DR[1]} to V_{DR[m]} is set to a high-level potential V_{DR}_{_{—}}_{H} or a low-level potential V_{DR}_{_{—}}_{L} (V_{DR}_{_{—}}_{H}>V_{DR}_{_{—}}_{L}). In addition, a configuration in which a circuit for generating the control signals G_{A[1]} to G_{A[m]} and a circuit for generating the driving potentials V_{DR[1]} to V_{DR[m]} are separately mounted may be employed. The column driving circuit 34 supplies instruction signals X_{[1]} to X_{[N]} to the signal lines 24.

The potential control circuit 36 generates and outputs a common potential V_{COM} commonly supplied to the pixel circuits P_{IX}. The common potential V_{COM} is set to a high-level potential V_{COM}_{_{—}}_{H} or a low-level potential V_{COM}_{_{—}}_{L} (V_{COM}_{_{—}}_{H}>V_{COM}_{_{—}}_{L}). The high-level potential V_{COM}_{_{—}}_{H} of the common potential V_{COM} and the high-level potential V_{DR}_{_{—}}_{H} of the driving potentials V_{DR[1]} to V_{DR[m]} are the same potential (for example, 15 V) and the low-level potential V_{COM}_{_{—}}_{L} of the common potential V_{COM} and the low-level potential V_{DR}_{_{—}}_{L} of the driving potentials V_{DR[1]} to V_{DR[m]} are the same potential (for example, 0 V).

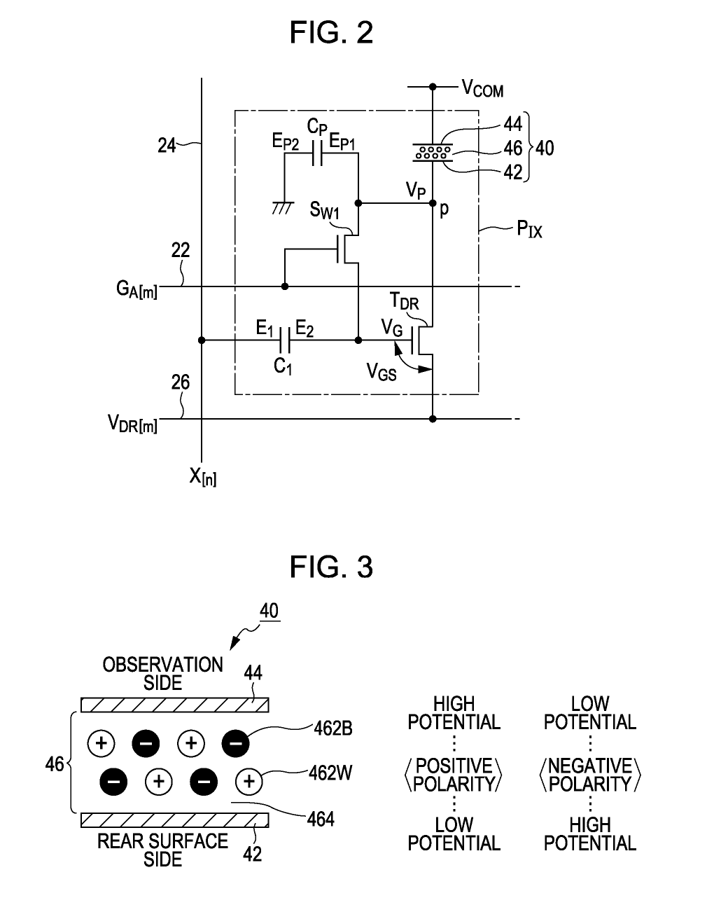

FIG. 2 is a circuit diagram of each pixel circuit P_{IX}. In FIG. 2, one pixel circuit P_{IX} located on an m-th (m=1 to M) row and an n-th column (n=1 to N) is representatively shown. The pixel circuit P_{IX} is an electronic circuit corresponding to each pixel of a display image and, as shown in FIG. 2, includes an electrophoretic element 40, a driving transistor T_{DR}, a switch S_{W1}, a capacitive element C₁, and an additional capacitive element C_{P}.

The electrophoretic element 40 is an electro-optical element having high resistance, which expresses a gradation using electrophoresis of charged particles, and includes a pixel electrode 42 and a counter electrode 44 facing each other and an electrophoretic layer 46 between both electrodes. As shown in FIG. 3, the electrophoretic layer 46 includes white and black charged particles 462 (462W and 462B) charged with opposite polarities and a dispersion medium 464 in which the charged particles 462 are electrophertically dispersed. For example, a configuration in which the charged particles 462 and the dispersion medium 464 are filled in a microcapsule or a configuration in which the charged particles 462 and the dispersion medium 464 are filled in a space partitioned by a partition wall is suitably employed.

The pixel electrode 42 is individually formed for each pixel circuit P_{IX} and the counter electrode 44 is continuously formed over the plurality of pixel circuits P_{IX}. As shown in FIG. 2, the pixel electrode 42 is connected to a circuit point (node) p in the pixel circuit P_{IX}. The common potential V_{COM} is supplied from the potential control circuit 36 to the counter electrode 44. In addition, hereinafter, a polarity of the voltage applied to the electrophoretic element 40 when the potential of the counter electrode 44 is higher than that of the pixel electrode 42 is conveniently referred to as a “positive polarity”. As shown in FIG. 3, hereinafter, the case where the counter electrode 44 is located on an observation side (an output side of a display image) rather than the pixel electrode 42, the white charged particles 462W are charged with a positive polarity and the black charged particles 462B are charged with a negative polarity is conveniently described. Accordingly, the gradation of the electrophoretic element 40 is black when a voltage having a positive polarity is applied and is white when a voltage having a negative polarity is applied.

The driving transistor T_{DR} of FIG. 2 is an N-channel type thin film transistor for driving the electrophoretic element 40 and is arranged on a path which connects the circuit point p (pixel electrode 42) and the driving potential line 26 of the m-th row. More specifically, the drain of the driving transistor T_{DR} is connected to the circuit point p (pixel electrode 42) and the source of the driving transistor T_{DR} is connected to the driving potential line 26. In addition, in the first embodiment, since the level of the voltages of the drain and the source of the driving transistor T_{DR} may be reversed, if the drain and the source are distinguished in terms of the level of the voltage, the drain and the source of the driving transistor T_{DR} are frequently reversed. However, in the following description, conveniently, the terminal (first terminal) of the driving potential line 26 side of the driving transistor T_{DR} is referred to as the source and the terminal (second terminal) of the pixel electrode 42 side is referred to as the drain.

The switch S_{W1} includes an N-channel type thin film transistor similarly to the driving transistor T_{DR} and controls electrical connection (electrical connection/non-electrical connection) between the gate of the driving transistor T_{DR} and the circuit point p (between the gate and the drain of the driving transistor T_{DR}). The gate of the switch S_{W1} is connected to the control line 22 of the m-th row. When the switch S_{W1} transitions to an on state, the gate and the drain of the driving transistor T_{DR} are connected (that is, diode-connected).

The capacitive element C₁ is a capacitor including an electrode E₁ and an electrode E₂. The electrode E₁ is connected to the signal line 24 of the n-th column and the electrode E₂ is connected to the gate of the driving transistor T_{DR}. The additional capacitive element C_{P} is a capacitor including an electrode E_{P1} and an electrode E_{P2}. The electrode E_{P1} is connected to the circuit point p and the electrode E_{P2} is connected to ground GND. In addition, if a sufficient capacitive component pertains to the electrophoretic element 40, the capacitive component of the electrophoretic element 40 may be used as the additional capacitive element C.

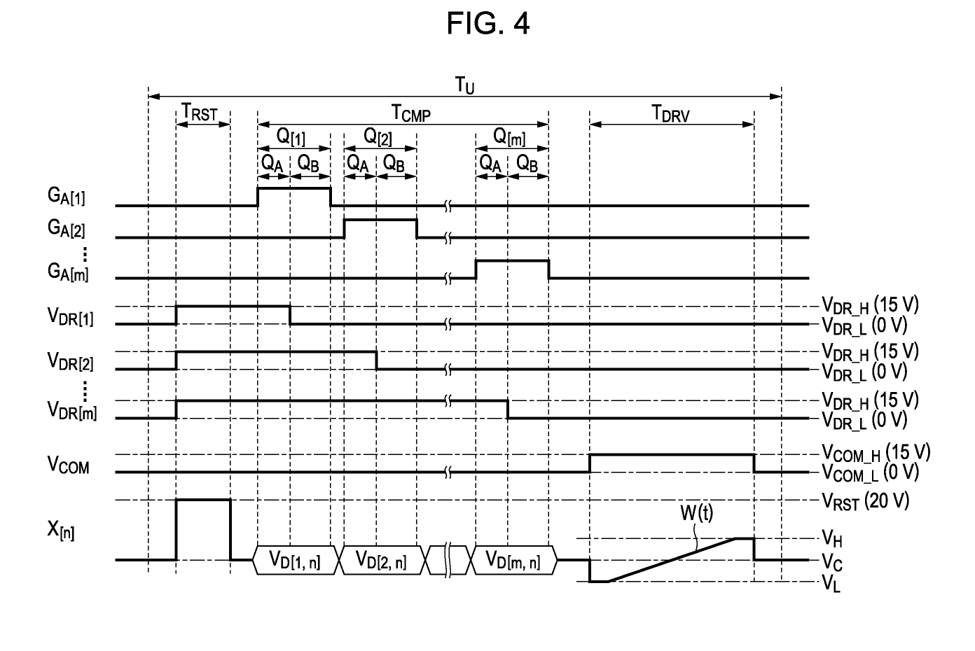

FIG. 4 is an explanatory diagram of an operation of the electro-optical device 100. As shown in FIG. 4, the electro-optical device 100 sequentially operates using a unit period (frame) T_{U} as a period. The unit period T_{U} of the first embodiment includes an initialization period T_{RST} as a “first period”, a compensation period T_{CMP}, as a “second period” and a “third period”, and an operation period T_{DRV} as a “fourth period”. In the initialization period T_{RST}, an initialization operation for initializing the potential V_{P} of the circuit point p (pixel electrode 42) of each pixel circuit P_{IX} is executed. The initialization operation is executed in parallel (concurrently) with respect to all (M×N) pixel circuits P_{IX} in the display unit 20.

In the compensation period T_{CMP}, a compensation operation for setting a voltage V_{GS} between the gate and the source of the driving transistor T_{DR} of each pixel circuit P_{IX} to a threshold voltage V_{TH} of the driving transistor T_{DR} and a writing operation for supplying a gradation potential V_{D[m,n]} according to a designated gradation of the pixel circuit P_{IX} to each pixel circuit P_{IX} are executed. The compensation period T_{CMP} is divided into M selection periods Q_{[1]} to Q_{[m]} corresponding to each row of the pixel circuit P_{IX}. In an m-th selection period Q_{[m]} in the compensation period T_{CMP}, the compensation operation and the writing operation are executed with respect to N pixel circuits P_{IX} of the m-th row.

In the operation period T_{DRV}, the gradation of the electrophoretic element 40 is variably controlled according to the gradation potential V_{D[m,n]} supplied to each pixel circuit P_{IX} in the compensation period T_{CMP}. More specifically, in a period of a time length according to the gradation potential V_{D[m,n]} of the operation period T_{DRV}, the driving transistor T_{DR} is controlled to an on state so as to execute a driving operation (pulse width modulation) for controlling the gradation of the electrophoretic element 40. The driving operation is executed in parallel (concurrently) with respect to all (M×N) pixel circuits P_{IX} in the display unit 20.

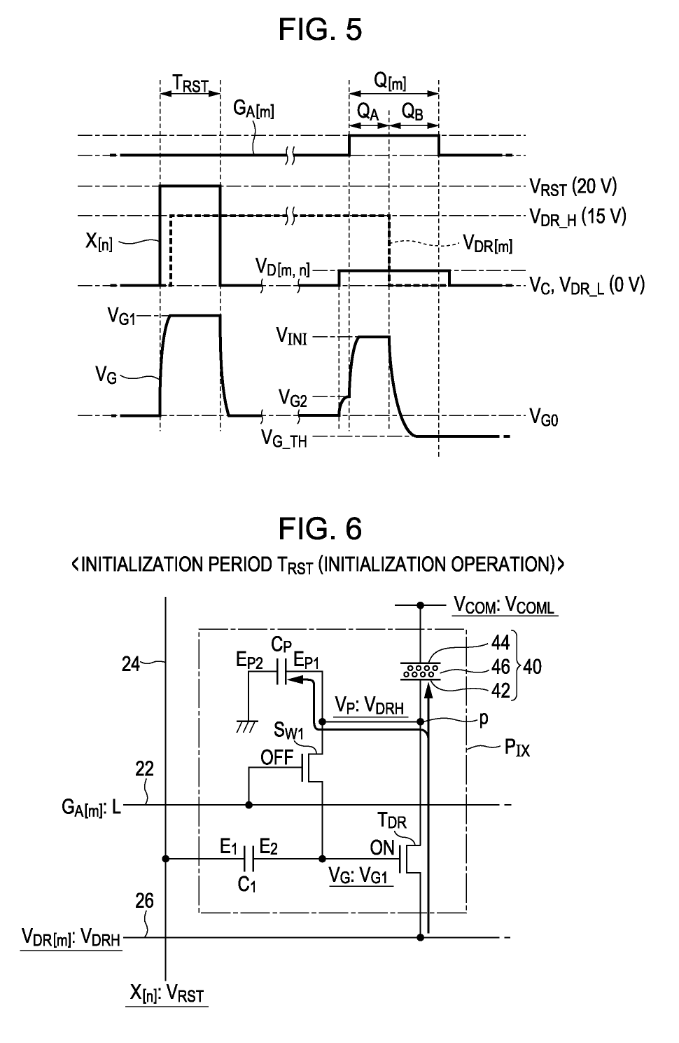

FIG. 5 is an explanatory diagram of a potential V_{G} of the gate of the driving transistor T_{DR} of the pixel circuit P_{IX} located at an m-th row and an n-th column. The operations of the above-described periods (T_{RST}, T_{CMP}, and T_{DRV}) will be described with reference to FIGS. 4 and 5. As shown in FIG. 5, it is assumed that, just before the initialization period T_{RST}, an instruction signal X_{[n]} supplied to the electrode E₁ of the capacitive element C₁ is set to a predetermined potential (hereinafter, referred to as a “reference potential”) V_{C} and the potential V_{G} of the gate of the driving transistor T_{DR} is set to a potential V_{G0}.

### 1. Initialization Period T_{RST}

When the initialization period T_{RST} starts, the column driving circuit 34 changes the instruction signals X_{[1]} to X_{[N]} of the signal lines 24 from the reference potential V_{C} to an initialization potential V_{RST} as shown in FIGS. 4 and 6. Since the capacitive element C₁ is interposed between each signal line 24 and the gate of the driving transistor T_{DR}, the potential V_{G} of the gate of the driving transistor T_{DR} is changed in tandem with the potential of the instruction signal X_{[n]} by capacitive coupling of the capacitive element C₁. If the capacitance of the gate of the driving transistor T_{DR} is conveniently ignored, the potential V_{G} is changed from the potential V_{G0} just before the initialization period T_{RST} to a high potential V_{G1} (V_{G1}=V_{G0}+(V_{RST}−V_{C})) by a change amount (V_{RST}−V_{C}) of the potential of the instruction signal X_{[n]}, as shown in FIG. 5. The row driving circuit 32 changes the driving potentials V_{DR[1]} to V_{DR[m]} of the driving potential lines 26 from a low-level potential V_{DR}_{_{—}}_{L} to a high-level potential V_{DR}_{_{—}}_{H}. In addition, since the control signal G_{A[m]} is held at a low level, the switch S_{W1} is held at an off state in the initialization period T_{RST}.

The initialization potential V_{RST} of the instruction signal X_{[n]} is set such that the driving transistor T_{DR} is held at an on state (V_{GS}=V_{G1}=V_{DR}_{_{—}}_{H}=V_{G0}+(V_{RST}−V_{C})−V_{DR}_{_{—}}_{H}>V_{TH}) in a state in which the driving potential V_{DR[m]} (the source potential of the driving transistor T_{DR}) is set to the high-level potential V_{DR}_{_{—}}_{H}. As described above, in the initialization period T_{RST}, since the driving transistor T_{DR} transitions to the on state, as denoted by an arrow of FIG. 6, the high-level potential V_{DR}_{_{—}}_{H} of the driving potential V_{DR[m]} is supplied from the driving potential line 26 to the circuit point p (pixel electrode 42) through the source and the drain of the driving transistor T_{DR}. That is, the potential V_{P} of the circuit point p is initialized to the high-level potential V_{DR}_{_{—}}_{H} (initialization operation).

In the initialization period T_{RST}, the potential control circuit 36 holds the common potential V_{COM} of the counter electrode 44 at a low-level potential V_{COM}. Accordingly, a negative voltage (hereinafter, referred to as a “reverse bias”) corresponding to a difference (V_{DR}_{_{—}}_{H}−V_{COM}_{_{—}}_{L}) between the high-level potential V_{DR}_{_{—}}_{H} of the driving potential V_{DR[m]} supplied from the driving potential line 26 to the pixel electrode 42 and the low-level potential V_{COM}_{_{—}}_{L} of the counter electrode 44 is applied to the electrophoretic element 40. By applying the above-described reverse bias, the gradation of all the electrophoretic elements 40 in the display unit 20 transitions to a white side. In addition, the additional capacitive element C_{P}, of which the electrode E_{P1} is connected to the circuit point p, is charged with charges according to the high-level potential V_{DR}_{_{—}}_{H} of the driving potential V_{DR[m]}. That is, the additional capacitive element C_{P} holds the high-level potential V_{DR}_{_{—}}_{H}.

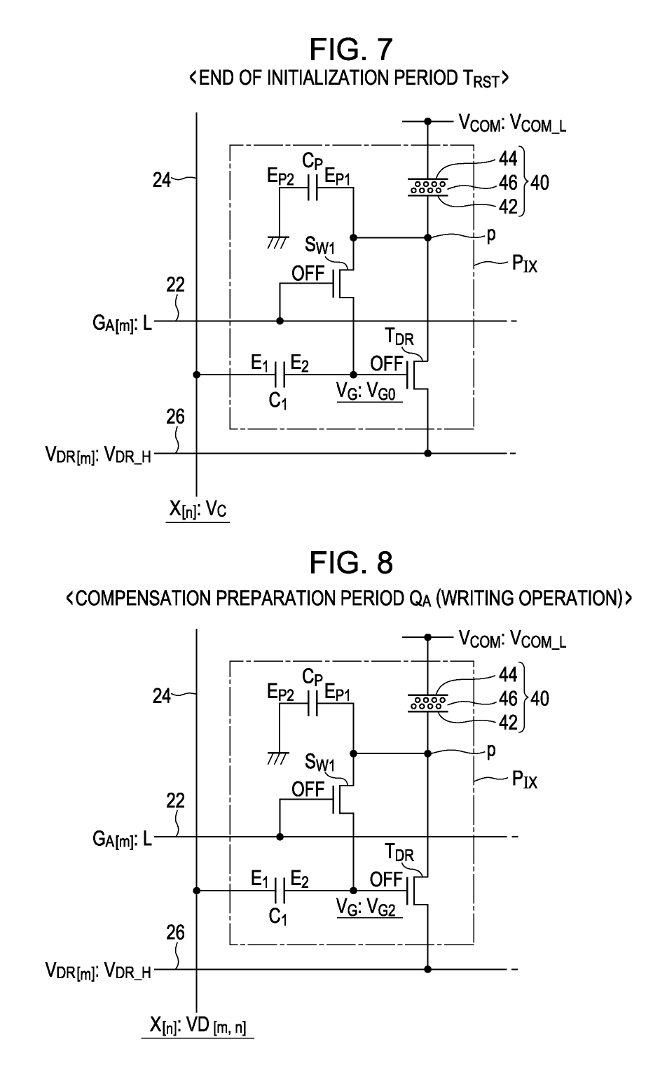

When the initialization period T_{RST} finishes, the column driving circuit 34 changes the instruction signals X_{[1]} to X_{[n]} of the signal lines 24 from the initialization potential V_{RST} to the reference potential V_{C}, as shown in FIGS. 4 and 7. The potential V_{G} of the gate of the driving transistor T_{DR} is decreased from the preceding potential V_{G1} (V_{G1}=V_{G0}+(V_{RST}−V_{C})) by the change amount (V_{RST}−V_{C}) of the potential of the instruction signal X_{[n]} and set to the preceding reference potential V_{G0} in the initialization period T_{RST}. Accordingly, when the initialization period T_{RST} finishes, the driving transistor T_{DR} transitions to an off state and the supply of the high-level potential V_{DR}_{_{—}}_{H} to the circuit point p is stopped. The driving potential V_{DR[m]} is continuously held at the high-level potential V_{DR}_{_{—}}_{H} even after the initialization period T_{RST} finishes.

### 2. Compensation Period T_{CMP}

As shown in FIG. 4, each selection period Q_{[m]} in the compensation period T_{CMP} is divided into a compensation preparation period Q_{A} as the “second period” and a compensation execution period Q_{B} as the “third period”. In the compensation preparation period Q_{A}, the potential V_{G} of the gate of the driving transistor T_{DR} is set to a predetermined potential (hereinafter, referred to as an “initial compensation value”) V_{INI} and, in the compensation execution period Q_{B}, the voltage V_{GS} between the gate and the source of the driving transistor T_{DR} is set to its threshold voltage V_{TH}. The common potential V_{COM} of the counter electrode 44 is held at the low-level potential V_{COM}_{_{—}}_{L} even in the compensation period T_{CMP}.

In the compensation preparation period Q_{A} of the selection period Q_{[m]}, the column driving circuit 34 sets the instruction signal X_{[n]} to the gradation potential V_{D[m,n]} (writing operation), as shown in FIGS. 4 and 8. The gradation potential V_{D[m,n]} is variably set according to the designated gradation of the pixel circuit P_{IX} located at the m-th row and the n-th column. The potential V_{G} of the gate of the driving transistor T_{DR} is changed in tandem with the potential of the instruction signal X_{[n]} by capacitive coupling of the capacitive element C₁. More specifically, the potential V_{G} is changed to a high potential V_{G2} (V_{G2}=V_{G0}+(V_{D[m,n]}=V_{C})) by a change amount (V_{D[m,n]}−V_{C}) of the potential of the instruction signal X_{[n]} as compared with the potential V_{G0} just after the initialization period T_{RST}, as shown in FIG. 5.

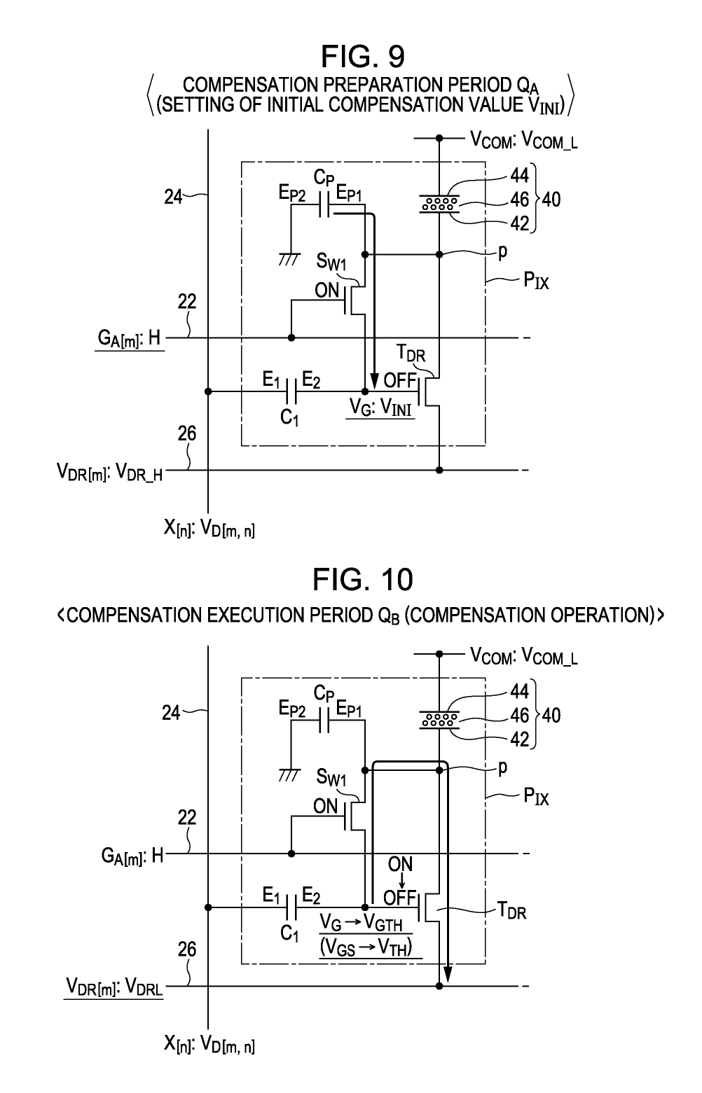

The row driving circuit 32 sets a control signal G_{A[m]} to a high level in the compensation preparation period Q_{A} so as to control the switch S_{W1} of the m-th row of each pixel circuit P_{IX} to an on state, as shown in FIGS. 4 and 9. When the switch S_{W1} transitions to the on state, as shown in FIG. 9, the additional capacitive element C_{P} is connected to the electrode E₂ of the capacitive element C₁ (the gate of the driving transistor T_{DR}) such that the charges accumulated in the capacitive element C₁ in the initialization period T_{RST} are moved to the gate (capacitive element C₁) of the driving transistor T_{DR}. Accordingly, the potential V_{G} of the gate of the driving transistor T_{DR} is changed to the initial compensation value V_{INI} exceeding the preceding potential V_{G2} (or the reference potential V_{C}), as shown in FIG. 5. More specifically, the initial compensation value V_{INI} is expressed by the following Equation 1 including a capacitance value c₁ of the capacitive element C₁ and a capacitance value c_{P} of the additional capacitive element C_{P}.

V_{INI}=αp·V_{DR}_{_{—}}_{H}+(1−αp)V_{G2}

(αp=c_{P}/(c_{P}+c₁)) (1)

In the compensation execution period Q_{B}, of the selection period Q_{[m]}, similar to the compensation preparation period Q_{A}, the instruction signal X_{[n]} is held at the gradation potential V_{D[m,n]} and the switch S_{W1} is held in the on state by the control signal G_{A[m]} of the high level. When the compensation execution period Q_{B} starts, the row driving circuit 32 decreases the driving potential V_{DR[m]} supplied to the source of the driving transistor T_{DR} from the high-level potential V_{DR}_{_{—}}_{H} to the low-level potential V_{DR}_{_{—}}_{L}, as shown in FIGS. 4 and 10. The high-level potential V_{DR}_{_{—}}_{H} and the low-level potential V_{DR}_{_{—}}_{L} of the driving potential V_{DR[m]} is set such that a difference between the initial compensation value V_{INI} of Equation 1 and the low-level potential V_{DR}_{_{—}}_{L} (that is, the voltage V_{GS} between the gate and the source of the driving transistor T_{DR}) exceeds the threshold voltage V_{TH}. Accordingly, when the driving potential V_{DR[m]} of a start point of the compensation execution period Q_{B} is decreased to the low-level potential V_{DR}_{_{—}}_{L}, the driving transistor T_{DR} transitions to the on state. As can be understood from Equation 1, as the capacitance value c_{P} of the additional capacitive element C_{P} and the capacitance value c₁ of the capacitive element C₁ are increased (that is, a coefficient αp is increased) or as the high-level potential V_{DR}_{_{—}}_{H} supplied to the circuit point p in the initialization period T_{RST} is higher than the potential V_{G2}, the initial compensation value V_{INI} may be reliably set to a high potential for controlling the driving transistor T_{DR} to the on state in the compensation execution period Q_{B}.

Even in the compensation execution period Q_{B}, since the on state of the switch S_{W1} (diode connection of the driving transistor T_{DR}) is held, when the driving transistor T_{DR} transitions to the on state, as denoted by an arrow in FIG. 10, the charges of the gate of the driving transistor T_{DR} are discharged to the driving potential line 26 through the switch S_{W1}, the circuit point p and the drain and the source of the driving transistor T_{DR}. Accordingly, as shown in FIG. 5, the potential V_{G} of the gate of the driving transistor T_{DR} is decreased from the initial compensation value V_{INI} with time and the driving transistor T_{DR} transitions to the off state (compensation operation) at a time when the voltage V_{GS} between the gate and the source reaches the threshold voltage V_{TH}.

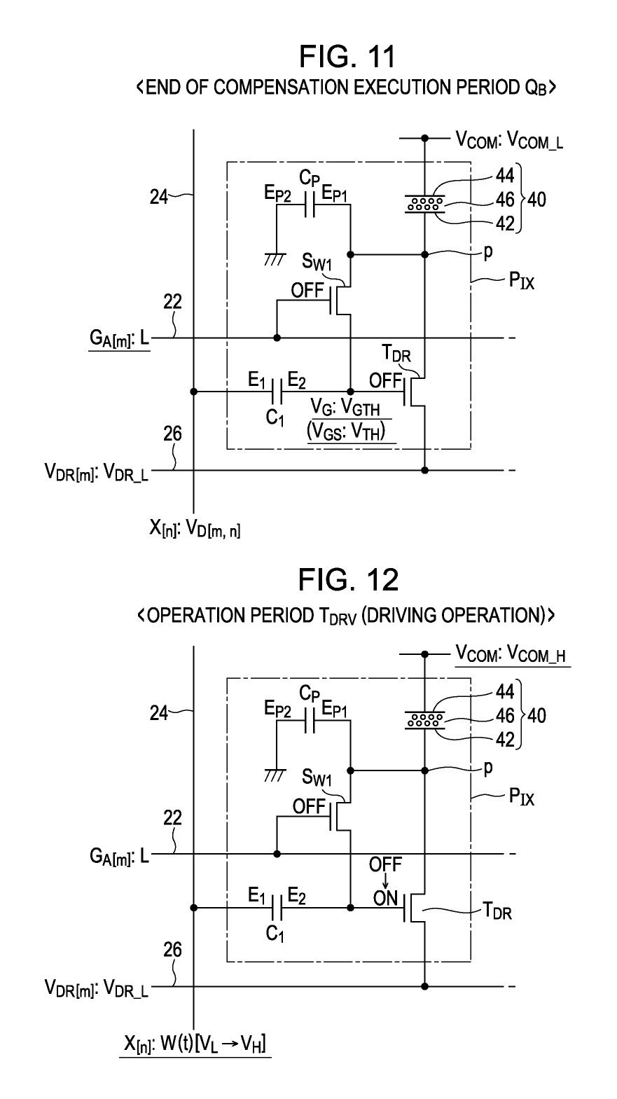

When the compensation execution period Q_{B} of the selection period Q_{[m]} finishes, the row driving circuit 32 changes the control signal G_{A[m]} to a low level so as to control the switch S_{W1} of each pixel circuit P_{IX} of the m-th row to the off state, as shown in FIGS. 4 and 11. That is, the diode connection of the driving transistor T_{DR} is released. As can be understood from the above description, at an end point of the compensation execution period Q_{B}, in a state of supplying the gradation potential V_{D[m,n]} to the electrode E₁ of the capacitive element C₁, the potential V_{G} of the gate of the driving transistor T_{DR} is set to a potential V_{G}_{_{—}}_{TH} (the voltage V_{GS} between the gate and the source of the driving transistor T_{DR} reaches the threshold voltage V_{TH} (V_{G}_{_{—}}_{TH}−V_{DR}_{_{—}}_{L}=V_{TH})).

The above operations are sequentially executed in the selection periods Q_{[1]} to Q_{[m]} of the compensation period T_{CMP}. In addition, since the capacitive element C₁ of each pixel circuit P_{IX} is directly connected to the signal line 24, the instruction signal X_{[n]} is changed to the gradation potential V_{D[m,n]} in the selection period Q_{[m]}, the potential of the electrode E₁ of the capacitive element C₁ of the pixel circuit P_{IX} of each row other than the m-th row is changed. The potential V_{G} of the gate of the driving transistor T_{DR} may be changed in tandem with the potential of the electrode E₁ and the driving transistor T_{DR} may transition to the on state. However, since the common potential V_{COM} of the counter electrode 44 is held at the low-level potential V_{COM}_{_{—}}_{L} within the compensation period T_{CMP}, transitioning the driving transistor T_{DR} to the on state does not influence the gradation of the electrophoretic element 40.

### 3. Operation Period T_{DRV}

When the operation period T_{DRV} after the elapse of the compensation period T_{CMP} starts, the potential control circuit 36 sets the common potential V_{COM} of the counter electrode 44 to the high-level potential V_{COM}_{_{—}}_{H}, as shown in FIGS. 4 and 12. The row driving circuit 32 continuously holds the driving potentials V_{DR[1]} to V_{DR[m]} at the low-level potential V_{DR}_{_{—}}_{L} from the compensation execution period Q_{B} of each selection period Q_{[m].}

The column driving circuit 34 sets the instruction signals X_{[1]} to X_{[N]} to the potential W(t) in the operation period T_{DRV}, as shown in FIGS. 4 and 12. As shown in FIG. 4, the potential W(t) is changed with time between a potential V_{L} and a potential V_{H} (V_{H}>V_{L}) such that the reference potential V_{C} is included in a fluctuation range (for example, using the reference potential V_{C} as a central value). The potential W(t) of the present embodiment is controlled to a ramp waveform (a saw-like wave) linearly changed from the potential V_{L} to the potential V_{H} from the start point to the end point of the operation period T_{DRV}. Accordingly, in the driving transistor T_{DR} of each pixel circuit P_{IX}, in a state in which the driving potential V_{DR[m]} of the driving potential line 26 (the potential of the source) is held at the low-level potential V_{DR}_{_{—}}_{L}, the potential V_{G} of the gate is changed (increased) in tandem with the potential W(t) of the instruction signal X_{[n]}. That is, the voltage V_{GS} between the gate and the source of the driving transistor T_{DR} is increased with time in the operation period T_{DRV}.

In the compensation period T_{CMP}, in a state in which the gradation potential V_{D[m,n]} is supplied to the electrode E₁ of the capacitive element C₁, the potential V_{G} (V_{G}_{_{—}}_{TH}) of the gate is set such that the voltage V_{GS} between the gate and the source of the driving transistor T_{DR} reaches the threshold voltage V_{TH}. Accordingly, in the operation period T_{DRV}, when the potential W(t) of the instruction signal X_{[n]} reaches the gradation potential V_{D[m,n]} of each pixel circuit P_{IX}, as shown in FIG. 12, the voltage V_{GS} between the gate and the source of the driving transistor T_{DR} of the pixel circuit P_{IX} reaches its threshold voltage V_{TH} and the driving transistor T_{DR} transitions to the on state. That is, the driving transistor T_{DR} of the pixel circuit P_{IX} located at the m-th row and the n-th column transitions from the off state to the on state at a variable time according to the designated gradation (gradation potential V_{D[m,n]}) of the pixel circuit P_{IX} in the operation period T_{DRV}. As can be understood from the above description, the pixel circuit P_{IX} functions as a comparison circuit for comparing the gradation potential V_{D[m,n]} with the potential W(t).

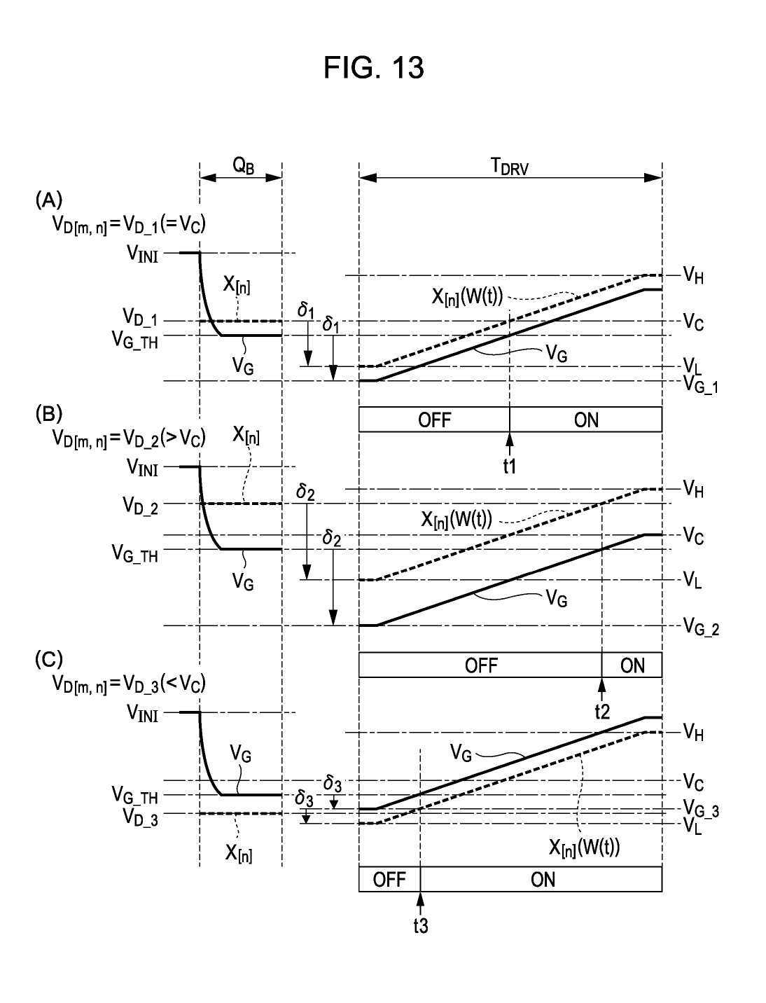

FIG. 13 is a schematic diagram showing a state in which the times t1, t2 and t3 when the driving transistor T_{DR} transitions from the off state to the on state in the operation period T_{DRV} are changed according to the gradation potential V_{D[m,n]}. The change in potential of the instruction signal X_{[n]} is denoted by a dotted line and the change in potential V_{G} of the gate of the driving transistor T_{DR} is denoted by a solid line.

In a part (A) of FIG. 13, the case where the gradation potential V_{D[m,n]} is set to a potential V_{D}_{_{—}}₁ in the compensation execution period Q_{B} of the selection period Q_{[m]} is considered. The potential V_{D}_{_{—}}₁ is equal to the reference potential V_{C} corresponding to the center of the amplitude of the potential W(t). If the potential W(t) of the instruction signal X_{[n]} is changed to the potential V_{L} at the start point of the operation period T_{DRV}, the potential V_{G} of the gate of the driving transistor T_{DR} is changed to the potential V_{G}_{_{—}}₁ lower than a potential V_{G}_{_{—}}_{TH} set in the compensation period T_{CMP} by a potential difference δ₁ between the gradation potential V_{D}_{_{—}}₁ and the potential V_{L}. The potential V_{G} is increased with time in tandem with the potential W(t) from the potential V_{G1} and the driving transistor T_{DR} transitions from the off state to the on state at a time t1 when reaching the potential V_{G}_{_{—}}_{TH} (that is, a time when the potential W(t) reaches the gradation potential V_{D}_{_{—}}₁).

In a part (B) of FIG. 13, the case where the gradation potential V_{D[m,n]} is set to a potential V_{D}_{_{—}}₂ higher than the reference potential V_{C} (V_{D}_{_{—}}₁) in the compensation execution period Q_{B} is considered. Since a change amount δ₂ in potential V_{G} of the gate of the driving transistor T_{DR} at the start point of the operation period T_{DRV} is greater than the change amount δ₁ of the part (A) of FIG. 13 by the gradation potential V_{D}_{_{—}}₂, the potential V_{G2} of the gate of the driving transistor T_{DR} just after the start of the operation period T_{DRV} is less than the potential V_{G}_{_{—}}₁ of the part (A) of FIG. 13. Accordingly, the driving transistor T_{DR} transitions to the on state at a time t2 later than the time t1 of the part (A) of FIG. 13.

In a part (C) of FIG. 13, the case where the gradation potential V_{D[m,n]} is set to a potential V_{D}_{_{—}}₃ lower than the reference potential V_{C} (V_{D}_{_{—}}₁) in the compensation execution period Q_{B} is considered. Since a change amount δ₃ in potential V_{G} of the gate of the driving transistor T_{DR} at the start point of the operation period T_{DRV} is less than the change amount δ₁ of the part (A) of FIG. 13 by the gradation potential V_{D}_{_{—}}₃, the potential V_{G}_{_{—}}₃ of the gate of the driving transistor T_{DR} just after the start of the operation period T_{DRV} exceeds the potential V_{G}_{_{—}}₁ of the part (A) of FIG. 13. Accordingly, the driving transistor T_{DR} transitions to the on state at a time t3 earlier than the time t1 of part (A) of FIG. 13.

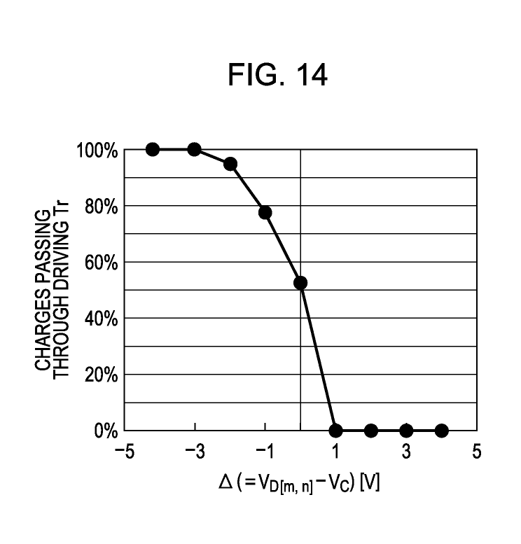

FIG. 14 is a graph of a relationship (logical value) between a difference Δ (Δ=V_{D[m,n]}−V_{C}) between the gradation potential V_{D[m,n]} and the reference potential V_{C} and a total amount of charges passing through the driving transistor T_{DR} within the operation period T_{DRV} (in other words, a ratio of a time when the driving transistor T_{DR} transitions to the on state in the operation period T_{DRV}). A numerical value of a vertical axis is normalized by setting a maximum value to 100%. As can be understood from FIGS. 13 and 14, in the first embodiment, as the gradation potential V_{D[m,n]} is increased (as the difference Δ with the reference potential V_{C} is increased), the time in which the driving transistor T_{DR} comes to be in the on state in the operation period T_{DRV} (the amount of charges passing through the driving transistor T_{DR}) is decreased.

When the driving transistor T_{DR} transitions to the on state at a time according to the gradation potential V_{D [m,n]}, since the low-level potential V_{DR}_{_{—}}_{L} of the driving potential V_{DR[m]} is supplied from the driving potential line 26 to the pixel electrode 42 through the driving transistor T_{DR}, a positive voltage (hereinafter, referred to as a “forward bias”) corresponding to a difference between the low-level potential V_{DR}_{_{—}}_{L} of the driving potential V_{DR[m]} and the high-level potential V_{COM}_{_{—}}_{H} of the common potential V_{COM} is applied to the electrophoretic element 40. Accordingly, black charged particles 462B of the electrophoretic element 40 are moved to the observation side and white charged particles 462W are moved to a rear surface side such that a display gradation transitions to a black side. When the operation period T_{DRV} finishes, the potential control circuit 36 changes the common potential V_{COM} to the low-level potential V_{COM}_{_{—}}_{L} (V_{COM}_{_{—}}_{L}=V_{DR}_{_{—}}_{L}). Accordingly, the application of the voltage to the electrophoretic element 40 is finished.

As described above, since the forward bias is applied to the electrophoretic element 40 with a variable time length according to the gradation potential V_{D[m,n]} (pulse width modulation), the gradation of the electrophoretic element 40 of each pixel circuit P_{IX} is controlled in multiple stages according to the gradation potential V_{D[m,n]} of the pixel circuit P_{IX}. More specifically, as the gradation potential V_{D[m,n]} is decreased (a time length in which the driving transistor T_{DR} transitions to the on state within the operation period T_{DRV} is increased), the gradation of the electrophoretic element 40 is controlled to a low gradation (gradation close to black). Accordingly, a multi-gradation image including a middle gradation is displayed on the display unit 20 in addition to white and black. In addition, a display image is changed by frequently repeating the unit period T_{U}.

In the above-described first embodiment, the driving transistor T_{DR} transitions to the on state in the initialization period T_{RST} such that the potential V_{P} of the circuit point p is initialized to the high-level potential V_{DR}_{_{—}}_{H}. Accordingly, when the driving transistor T_{DR} is diode-connected in the compensation execution period Q_{B}, it is possible to enable current to reliably flow between the drain (gate) and the source (that is, the compensation operation is executed). That is, in spite of the configuration in which the electro-optical element (electrophoretic element 40) with high resistance is employed, it is possible to efficiently compensate for error of characteristics (threshold voltage V_{TH}) of the driving transistor T_{DR} (further, it is possible to suppress gradation unevenness of a display image). By controlling the driving transistor T_{DR} to the on state, since the high-level potential V_{DR}_{_{—}}_{H} is supplied to the circuit point p, an element dedicated to initialization (supply of high-level potential V_{DR}_{_{—}}_{H}) of the potential V_{P} of the circuit point p does not need to be mounted in the pixel circuit P_{IX}. Accordingly, it is possible to simplify the configuration of the pixel circuit P_{IX}.

However, in order to start the compensation operation in the compensation execution period Q_{B}, the potential (driving potential V_{DR[m]}) of the source of the driving transistor T_{DR} needs to be lowered as compared to the potential V_{G} of the gate such that the voltage V_{GS} between the gate and the source of the driving transistor T_{DR} exceeds the threshold voltage V_{TH}. In the first embodiment, since the potential V_{G} (V_{G2}) of the gate of the driving transistor T_{DR} is increased to the initial compensation value V_{INI} by connecting the additional capacitive element C_{P} and the capacitive element C₁ in the compensation preparation period Q_{A}, it is possible to relax the conditions necessary for the low-level potential V_{DR}_{_{—}}_{L} of the driving potential V_{DR[m]} as compared to the configuration (hereinafter, referred to as a “comparison example”) in which the potential V_{G} is not increased in the compensation preparation period Q_{A}.

For example, on the assumption that the threshold voltage V_{TH} is 1 V, the comparison example of starting the compensation operation in a state in which the potential V_{G} of the gate of the driving transistor T_{DR} is set to the potential V_{G2} of FIG. 8 (that is, the configuration in which the compensation preparation period Q_{A} of FIG. 9 is omitted) is considered. In the case where the potential V_{G2} is −3 V, in order to realize the compensation operation in the comparison example, the low-level potential V_{DR}_{_{—}}_{L} of the driving potential V_{DR[m]} needs to be set to −4 V. In the first embodiment, since the potential V_{G} is increased to, for example, the initial compensation value V_{INI} of 3 V by connecting the additional capacitive element C_{P} to the gate of the driving transistor T_{DR} in the compensation preparation period Q_{A}, the low-level potential V_{DR}_{_{—}}_{L} of the driving potential V_{DR[m]} is set to 2 V or less. That is, since the conditions necessary for the low-level potential V_{DR}_{_{—}}_{L} of the driving potential V_{DR[m]} are relaxed, as in the first embodiment, it is possible to set the potentials (V_{DR}_{_{—}}_{H}, V_{DR}_{_{—}}_{L}) of the driving potential V_{DR[m]} to the same potential as the potentials (V_{COM}_{_{—}}_{H}, V_{COM}_{_{—}}_{L}) of the common potential V_{COM}. As described above, it is possible to simplify the configuration for generating the potentials by commonly using the potentials (reducing the number of kinds of potentials). In addition, for the compensation operation of the compensation execution period Q_{B}, the driving transistor T_{DR} is diode-connected in the compensation preparation period Q_{A} such that the additional capacitive element C_{P} and the capacitive element C₁ are connected so as to increase the potential V_{G}. That is, the initial compensation value V_{INI} is set along with the diode connection of the driving transistor T_{DR}. Accordingly, for example, it is possible to simplify the configuration of the pixel circuit P_{IX} as compared to a configuration in which a dedicated element for increasing the potential V_{G} before the compensation operation is specially mounted.

However, in the configuration in which a voltage (DC component) of one polarity is continuously applied to the electrophoretic element 40, the characteristics of the electrophoretic element 40 may deteriorate. In the first embodiment, the application and the stoppage of the forward bias to the electrophoretic element 40 are selectively executed in the operation period T_{DRV} (that is, the negative voltage is not applied to the electrophoretic element 40 in the operation period T_{DRV}), the reverse bias of the polarity opposite to the polarity of the voltage applied in the operation period T_{DRV} is applied to the electrophoretic element 40 in the initialization period T_{RST}. Accordingly, it is possible to suppress deterioration of the electrophoretic element 40 due to the application of the DC component, as compared to the configuration in which the reverse bias is not applied. In addition, in order to realize the compensation operation, since the high-level potential V_{DR}_{_{—}}_{H} supplied to the circuit point p in the initialization period T_{RST} is used for applying the reverse bias to the electrophoretic element 40, it is possible to simplify the configuration of the pixel circuit P_{IX} as compared to the configuration in which the element dedicated to the application of the reverse bias is mounted in the pixel circuit P_{IX}.

### B: Second Embodiment

Next, a second embodiment of the invention will be described. The elements having the same operations or functions as the first embodiment are denoted by reference numerals used in the above description and the description thereof will be properly omitted.

In the first embodiment, the charges accumulated in the additional capacitive element C_{P} in the initialization period T_{RST} are supplied to the gate of the driving transistor T_{DR} in the compensation preparation period Q_{A} such that the potential V_{G} is set to the initial compensation value V_{INI} (the potential higher than the potential V_{G0}). The second embodiment is different from the first embodiment in a method of setting (boosting) the potential V_{G} of the gate of the driving transistor T_{DR} in the compensation preparation period Q_{A} to the initial compensation value V_{INI}. The configuration of the pixel circuit P_{IX} is equal to that of the first embodiment.

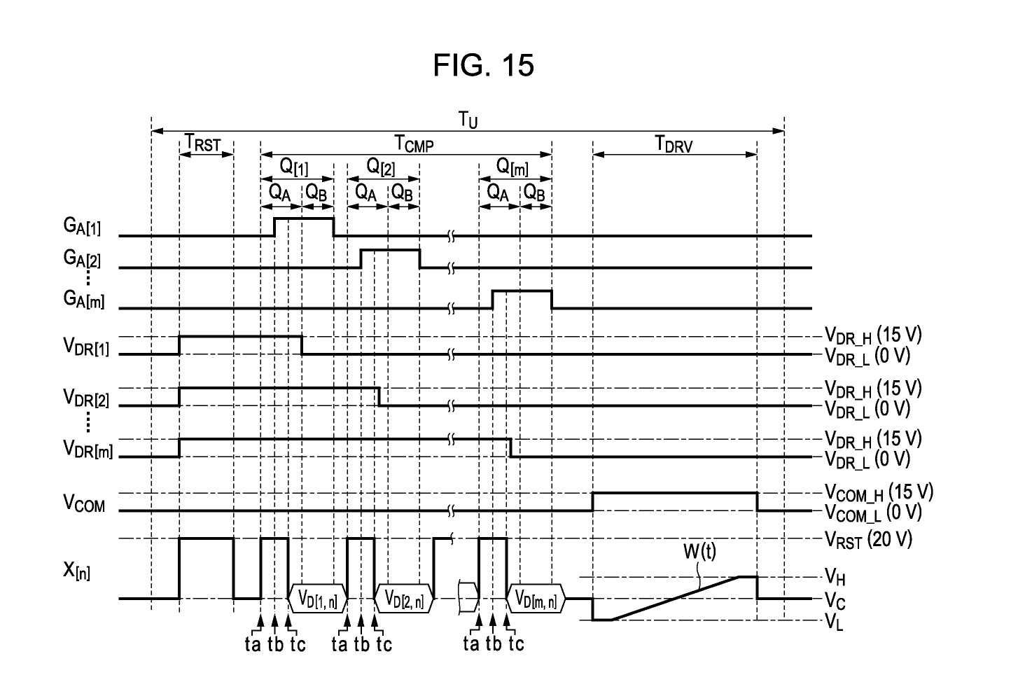

FIG. 15 is an explanatory diagram of an operation within a unit period T_{U} of the second embodiment. As can be understood from FIG. 15, the operations of the periods (the initialization period T_{RST}, the compensation execution period Q_{B}, the operation period T_{DRV}) other than the compensation preparation period Q_{A} are equal to those of the first embodiment. Hereinafter, only the operation of the compensation preparation period Q_{A} within the selection period Q_{[m]} will be described.

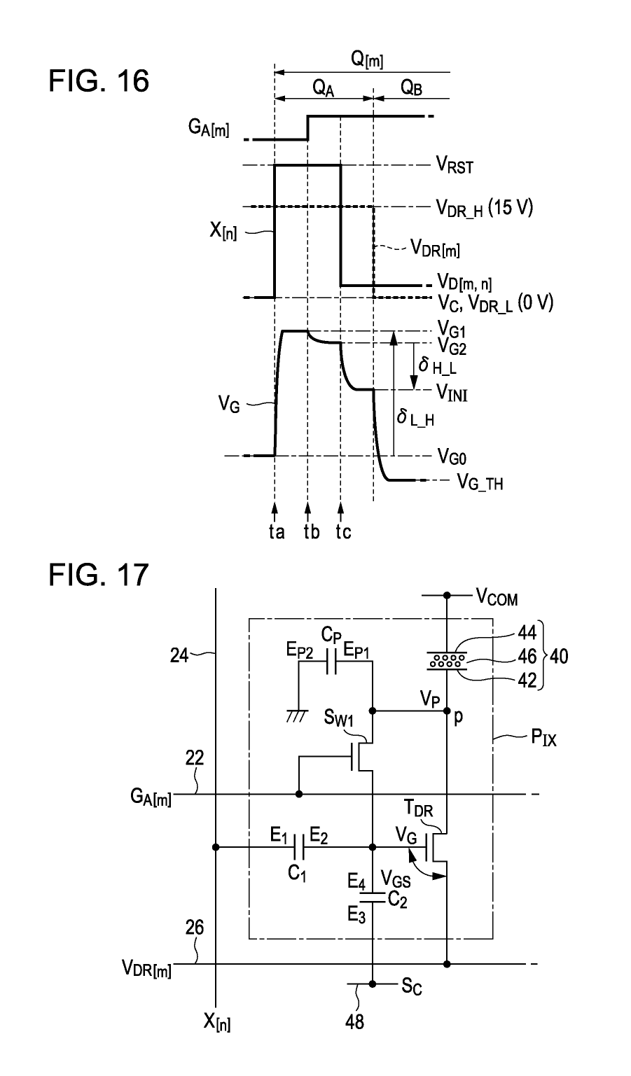

FIG. 16 is an explanatory diagram of the operation within the selection period Q_{[m]}. As shown in FIGS. 15 and 16, the column driving circuit 34 increases the instruction signal X_{[n]} from the reference potential V_{C} to the initialization potential V_{RST} at a time ta of the compensation preparation period Q_{A} of the selection period Q_{[m]}. The potential V_{G} of the gate of the driving transistor T_{DR} is increased from the potential V_{G0} to the potential V_{G1} in tandem with the change in the instruction signal X_{[n]} at the time ta. At the time ta, the control signal G_{A[m]} is set to a low level such that the switch S_{W1} is held in the off state. That is, the additional capacitive element C_{P} is electrically insulated from the gate (capacitive element C₁) amount δ_{L}_{_{—}}_{H} (V_{G1}=V_{G0}+δ_{L}_{_{—}}_{H}) of the potential V_{G} is equal to the change amount (V_{RST}−V_{C}) of the potential of the instruction signal X_{[n].}

In a time tb within the compensation preparation period Q_{A}, the row driving circuit 32 changes the control signal G_{A[m]} to the high level such that the switch S_{W1} of each pixel circuit P_{IX} of the m-th row transitions to the on state. Accordingly, the driving transistor T_{DR} is diode-connected and the additional capacitive element C_{P} is connected to the gate of the driving transistor T_{DR}. Since the potential V_{G} of the gate is increased to the potential V_{G1} at a time to such that the driving transistor T_{DR} transitions to the on state, if the potential V_{G} of the gate of the driving transistor T_{DR} decreases with time after the time tb and reaches the potential V_{G2} (V_{G2}−V_{DR}_{_{—}}_{H}+V_{TH}) in which the voltage V_{GS} between the gate and the source of the driving transistor T_{DR} reaches the threshold voltage V_{TH}, the driving transistor T_{DR} transitions to the off state.

When a time tc after the elapse of the time tb is reached, the column driving circuit 34 decreases the instruction signal X_{[n]} from the initialization potential V_{RST} to the gradation potential V_{D[m,n]}. The potential V_{G} of the gate of the driving transistor T_{DR} decreases the potential V_{G2} to the initial compensation value V_{INI} in tandem with the change in the potential of the instruction signal X_{[n]}. At the time tc, the additional capacitive element C_{P} is connected to the gate of the driving transistor T_{DR} through the switch S_{W1} of the on state. Accordingly, the decrease amount δ_{H}_{_{—}}_{L} (V_{INI}=V_{G2}−δ_{H}_{_{—}}_{L}) just after the time tc becomes a voltage (δ_{H}_{_{—}}_{L}=α1 (V_{RST}−V_{D[m,n]}), α1=c₁/(c₁+c_{P})) obtained by dividing the change amount (V_{RST}−V_{D[m,n]}) of the potential of the instruction signal X_{[n]} according to the capacitance value c₁ of the capacitive element C₁ and the capacitance value c_{P} of the additional capacitive element C_{P}. That is, the change amount δ_{H}_{_{—}}_{L} of the potential V_{G} at the time tc is less than the change amount δ_{L}_{_{—}}_{H} of the potential V_{G} at the time ta. Using the above-described difference between the change amount δ_{H}_{_{—}}_{L} and the change amount δ_{L}_{_{—}}_{H}, the initial compensation value V_{INI} is set to a potential exceeding the potential V_{G0} of the gate before the start of the initialization period T_{RST}, similarly to the first embodiment. In the compensation execution period Q_{B} after the elapse of the compensation preparation period Q_{A}, similarly to the first embodiment, the driving potential V_{DR[m]} is changed to the low-level potential V_{DR}_{_{—}}_{L} so as to execute the compensation operation.

Even in the second embodiment, the same effects as the first embodiment are realized. In the second embodiment, since the difference between the change amount δ_{H}_{_{—}}_{L} and the change amount δ_{L}_{_{—}}_{H} of the potential V_{G} of the gate of the driving transistor T_{DR} is used to set the initial compensation value V_{INI}, it is possible to set the initial compensation value V_{INI} to a high potential even when the charges accumulated in the additional capacitive element C_{P} are less. Accordingly, as compared to the first embodiment in which the charges of the additional capacitive element C_{P} are used to set the initial compensation value V_{INI}, the high-level potential V_{DR}_{_{—}}_{H} for charging the additional capacitive element C_{P} in the initialization period T_{RST} may be a low potential. While the instruction signal X_{[n]} needs to be increased to the initialization potential V_{RST} in the compensation preparation period Q_{A} of each selection period Q_{[m]} in the second embodiment, the instruction signal X_{[n]} does not need to be changed to the initialization potential V_{RST} in the compensation preparation period Q_{A} in the first embodiment. Accordingly, according to the first embodiment, the number of times of potential change of the instruction signal X_{[n]} is reduced as compared to the first embodiment, power consumed when charging or discharging the signal line 24 is reduced.

### C: Third Embodiment

FIG. 17 is a circuit diagram of a pixel circuit P_{IX} according to a third embodiment of the invention. As shown in FIG. 17, the pixel circuit P_{IX} of the third embodiment has a configuration in which a capacitive element C₂ is added to the pixel circuit P_{IX} of the first embodiment. The capacitive element C₂ is a capacitor including an electrode E₃ and an electrode E₄. The electrode E₃ is connected to a capacitive line 48 and the electrode E₄ is connected to the gate of the driving transistor T_{DR}. The capacitive line 48 is a wire commonly connected to all the pixel circuit P_{IX} in the display unit 20. The potential control circuit 36 generates and supplies a capacitive potential S_{C} to the capacitive line 48.

In the first embodiment, the instruction signal X_{[n]} is set to the initialization potential V_{RST} in the initialization period T_{RST} so as to execute the initialization operation and the instruction signal X_{[n]} is set to the variable potential W(t) in the operation period T_{DRV} so as to execute the driving operation. In the third embodiment, the initialization operation and the driving operation are realized using the capacitive potential S_{C}, instead of the instruction signal X_{[n]}. In addition, the same method of the second embodiment (the method of using the difference between the increase amount δ_{L}_{_{—}}_{H} and the decrease amount δ_{H}_{_{—}}_{L} of the potential V_{G}) is employed in the setting of the initial compensation value V_{INI} of the compensation preparation period Q_{A}.

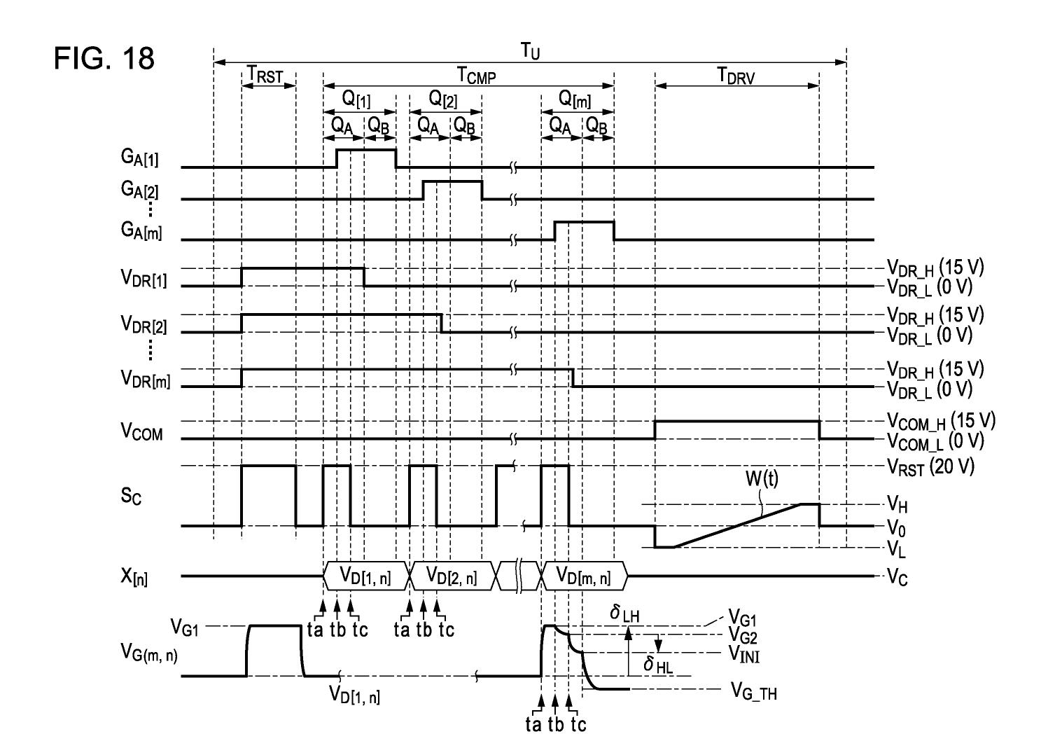

FIG. 18 is an explanatory diagram of the operation in the unit period T_{U} of the third embodiment. Similarly to the first embodiment, the initialization operation is executed in parallel with respect to the pixel circuits P_{IX} in the initialization period T_{RST}, the writing operation and the compensation operation are sequentially executed in row units in the compensation period T_{CMP}, and the driving operation is executed in parallel with respect to the pixel circuits P_{IX} in the operation period T_{DRV}.

### 1. Initialization Period T_{RST}

In the initialization period T_{RST}, as shown in FIG. 18, the control signals G_{A[1]} to G_{A[m]} are set to the low level such that the switch S_{W1} of each pixel circuit P_{IX} is held in the off state, and the common potential V_{COM} of the counter electrode 44 is set to the low-level potential V_{COM}_{_{—}}_{L}. The column driving signal 34 holds the instruction signal X_{[n]} to the reference potential V_{C}.

When the initialization period T_{RST} starts, the potential control circuit 36 changes the capacitive potential S_{C} of the capacitive line 48 from the potential V₀ to the initialization potential V_{RST}. The potential V₀ is set to, for example, the same potential (for example, a ground potential (0 V)) as the reference potential V_{C}. Since the capacitive element C₂ is interposed between the capacitive line 48 and the gate of the driving transistor T_{DR}, the potential V_{G} of the gate of the driving transistor T_{DR} is changed from the potential V_{G0} to the potential V_{G2} in tandem with the capacitive potential S_{C} by capacitive coupling of the capacitive element C₂. The change amount δ_{L}_{_{—}}_{H} (V_{G2}=V_{G0}+δ_{L}_{_{—}}_{H}) of the potential V_{G} in tandem with the capacitive potential S_{C} becomes a voltage (δ_{L}_{_{—}}_{H}=β2(V_{RST}−V₀), β2=c₂/(c₁+c₂)) obtained by dividing the change amount (V_{RST}−V₀) of the capacitive potential S_{C} according to the capacitance value c₁ of the capacitive element C₁ and the capacitance value c₂ of the capacitive element C₂.

The row driving circuit 32 sets the driving potentials V_{DR[1]} to V_{DR[m]} of the driving potential lines 26 to the high-level potential V_{DR}_{_{—}}_{H} in the initialization period T_{RST}. The initialization potential V_{RST} of the capacitive potential S_{C} is set such that the driving transistor T_{DR} is held in an on state (V_{GS}=V_{G1}=V_{DR}_{_{—}}_{H}>V_{TH}) in a state in which the driving potential V_{DR[m]} is set to the high-level potential V_{DR}_{_{—}}_{H} (for example, V_{RST}=25 V). As described above, in the initialization period T_{RST}, since the driving transistor T_{DR} is controlled to the on state, similarly to the first embodiment, the potential V_{P} of the circuit point p is initialized to the high-level potential V_{DR}_{_{—}}_{H} supplied from the driving potential line 26 through the driving transistor T_{DR} (initialization operation). Accordingly, the reverse bias is applied to the electrophoretic element 40 and the high-level potential V_{DR}_{_{—}}_{H} is held in the additional capacitive element C_{P}. When the initialization period T_{RST} finishes, the capacitive potential S_{C} is set to the potential V₀ just before the initialization period T_{RST} and the driving transistor T_{DR} transitions to the off state. Accordingly, the supply of the high-level potential V_{DR}_{_{—}}_{H} to the circuit point p is stopped.

### 2. Compensation Period T_{CMP}

In the selection period Q_{[m]} (Q_{A}, Q_{B}) of the compensation period T_{CMP}, the column driving circuit 34 sets the instruction signal X_{[n]} to the gradation potential V_{D[m,n]}. The potential control circuit 36 increases the capacitive potential S_{C} to the initialization potential V_{RST} at the time ta of the compensation preparation period Q_{A}. Accordingly, the potential V_{G} of the gate of the driving transistor T_{DR} is increased to the potential V_{G1} in tandem with the change in the capacitive potential S_{C}. At the time ta, since the switch S_{W1} is held in the off state such that the capacitive element C_{P} is electrically insulated from the gate of the driving transistor T_{DR}, the change δ_{L}_{_{—}}_{H} of the potential V_{G} at the time ta becomes a voltage (δ_{L}_{_{—}}_{H}=β2(V_{RST}−V₀) obtained by dividing the change amount (V_{RST}−V₀) in the potential of the capacitive potential S_{C} by the capacitive element C₁ and the capacitive element C₂, similarly to the change of the initialization period T_{RST}.

At the time tb of the compensation preparation period Q_{A} in the selection period Q_{[m]}, the row driving circuit 32 changes the control signal G_{A[m]} to the high level so as to control the switch S_{W1} of each pixel circuit P_{IX} of the m-th row to the on state. Accordingly, similarly to the second embodiment, the potential V_{G} of the gate of the driving transistor T_{DR} is decreased to a potential V_{G2} (V_{G2}=V_{DR}_{_{—}}_{H}+V_{TH}) in which the voltage V_{GS} between the gate and the source becomes the threshold voltage V_{TH}.

When a time tc after the elapse of the time tb is reached, the potential control circuit 36 decreases the capacitive potential S_{C} from the initialization potential V_{RST} to the potential V₀. The potential V_{G} of the gate of the driving transistor T_{DR} is decreased from the potential V_{G2} to the initial compensation value V_{INI} in tandem with the change in the capacitive potential S_{C}. At the time tc, since the additional capacitive element C_{P} is connected to the gate of the driving transistor T_{DR}, the change δ_{H}_{_{—}}_{L} (V_{INI}=V_{G2}−δ_{H}_{_{—}}_{L}) of the potential V_{G} at the time tc becomes a voltage (δ_{H}_{_{—}}_{L}−γ2 (V_{RST}−V₀), γ2=c₂/(c₁+c₂+c_{P})) obtained by dividing the change (V_{RST}−V₀) of the capacitive potential S_{C} by the capacitive element C₁, the capacitive element C₂ and the additional capacitive element C_{P}. That is, the change δ_{H}_{_{—}}_{L} of the potential V_{G} at the time tc is less than the change δ_{L}_{_{—}}_{H} of the potential V_{G} at the time ta. Using the above-described difference between the change δ_{H}_{_{—}}_{L} and the change δ_{L}_{_{—}}_{H}, the initial compensation value V_{INI} is set to a potential exceeding the potential V_{G0} of the gate before the start of the initialization period T_{RST}, similarly to the first embodiment.

In the compensation execution period Q_{B} after the elapse of the compensation preparation period Q_{A} in the selection period Q_{[m]}, the driving potential V_{DR[m]} is changed to the low-level potential V_{DR}_{_{—}}_{L} so as to execute the compensation operation. That is, similarly to the first embodiment or the second embodiment, at the end point of the compensation execution period Q_{B}, in a state in which the gradation potential V_{D[m,n]} is supplied to the electrode E₁ of the capacitive element C₁, the potential V_{G} of the gate of the driving transistor T_{DR} is set to a potential V_{G}_{_{—}}_{TH} (V_{G}_{_{—}}_{TH}−V_{DR}_{_{—}}_{L}=V_{TH})).

### 3. Operation Period T_{DRV}

In the operation period T_{DRV}, in a state in which the instruction signals X_{[1]} to X_{[N]} of the signal lines 24 are held at the reference potential V_{C} and the driving potentials V_{DR[i]} to V_{DR[m]} of the driving potential line 26 are held at the low-level potential V_{DR}_{_{—}}_{L}, the potential control circuit 36 sets the capacitive potential S_{C} to the potential W(t). The potential W(t) is changed with time from the potential V_{L} to the potential V_{H} from the start point to the end point of the operation period T_{DRV}, similarly to the first embodiment. Since the capacitive element C₂ is interposed between the capacitive line 48 and the gate of the driving transistor T_{DR}, the potential V_{G} of the gate of the driving transistor T_{DR} of each pixel circuit P_{IX} is in tandem with the potential W(t) by capacitive coupling of the capacitive element C₂. Accordingly, similarly to the first embodiment, the driving transistor T_{DR} transitions from the off state to the on state at a time according to the gradation potential V_{D[m,n]} of the operation period T_{DRV} and the forward bias begins to be applied to the electrophoretic element 40. In addition, while only the capacitive element C₁ pertains to the gate of the driving transistor T_{DR} in the first embodiment, the capacitive element C₁ and the capacitive element C₂ pertain to the gate of the driving transistor T_{DR} in the present embodiment. Therefore, in the present embodiment, in order to change the potential V_{G} in the same range as the first embodiment, the potential W(t) of the capacitive potential S_{C} needs to be changed with a large amplitude as compared to the potential W(t) of the first embodiment.

Even in the above-described third embodiment, the same effects as the first embodiment are realized. In the third embodiment, since the capacitive potential S_{C} is used in the initialization operation or the driving operation, the operation for changing the instruction signal X_{[n]} to the initialization potential V_{RST} in the initialization period T_{RST} or the operation for changing the instruction signal X_{[n]} from the potential V_{L} to the potential V_{H} in the operation period T_{DRV} is not necessary. That is, according to the third embodiment, since the amplitude of the instruction signal X_{[n]} is lower than that of the first embodiment, pressure resistance performance necessary for the column driving circuit 34 is reduced. Since only the capacitive element C₁ pertains to the gate of the driving transistor T_{DR} in the first embodiment, as compared to the third embodiment in which the capacitive element C₁ and the capacitive element C₂ pertain to the gate of the driving transistor T_{DR}, the charging/discharging of the charges when the potential V_{G} of the gate of the driving transistor T_{DR} is changed is reduced (further, power consumption is reduced).

### D: Fourth Embodiment

In order to enable the driving transistor T_{DR} from the off state to the on state in the operation period T_{DRV}, the voltage V_{GS} between the gate and the source of the driving transistor T_{DR} needs to be changed with time. As the method of changing the voltage V_{GS}, there is a method of changing the potential V_{G} of the gate and a method of changing the potential of the source. The first embodiment of setting the instruction signal X_{[n]} to the potential W(t) or the third embodiment of setting the capacitive potential S_{C} to the potential W(t) are detailed examples of the former method of changing the voltage V_{G} of the gate of the driving transistor T_{DR}. In contrast, the below-described fourth embodiment employs the latter method of changing the potential (that is, the driving potential V_{DR[m]}) of the source of the driving transistor T_{DR} in the operation period T_{DRV} with time. The configuration of the pixel circuit P_{IX} is equal to that of the first embodiment.

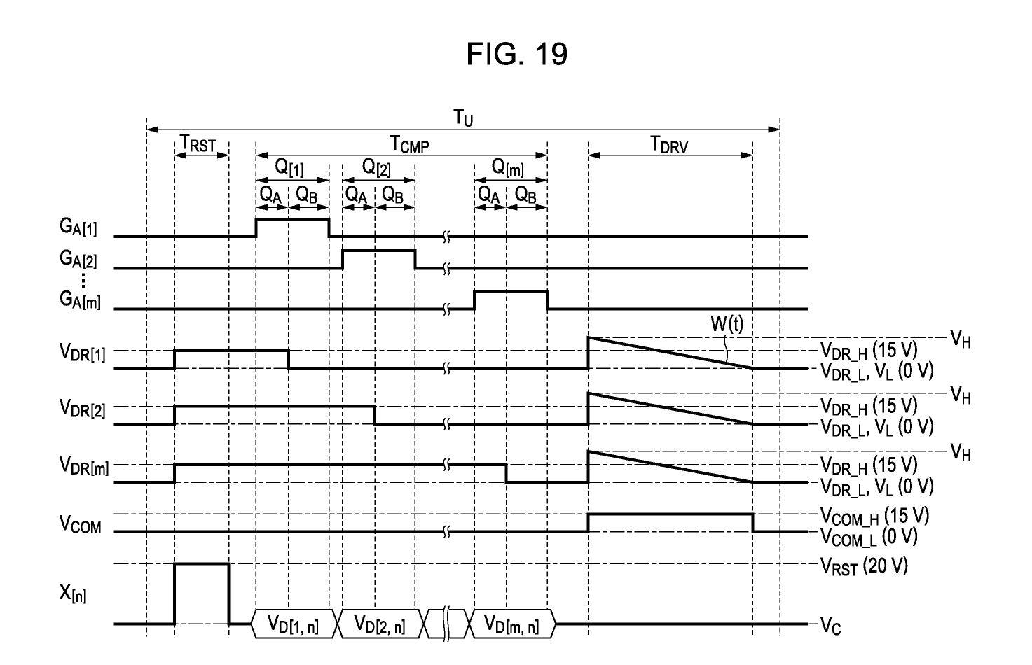

FIG. 19 is an explanatory diagram of an operation within a unit period T_{U} of the fourth embodiment. The operation of the initialization period T_{RST} and the compensation period T_{CMP}, are equal to those of the first embodiment and the description thereof will be omitted. Hereinafter, the operation of the operation period T_{DRV} will be described.

The column driving circuit 34 holds the instruction signals X_{[1]} to X_{[n]} within the operation period T_{DRV} at the reference potential V_{C}. Accordingly, the potential V_{G} of the gate of the driving transistor T_{DR} is fixed within the operation period T_{DRV}. In contrast, the row driving circuit 32 sets the driving potentials V_{DR[T]} to V_{DR[m]} supplied to the driving potential lines 26 (sources of the driving transistors T_{DR} of the pixel circuits P_{IX}) to the potential W(t). As shown in FIG. 19, the potential W(t) decreases with time from the potential V_{H} to the potential V_{L} (V_{L}=V_{DR}_{_{—}}_{L}=0V) from the start point to the end point of the driving period T_{DRV}. Accordingly, the voltage V_{GS} between the gate and the source of the driving transistor T_{DR} is increased with time within the operation period T_{DRV}, similarly to the first embodiment to the third embodiment. When the voltage V_{GS} of each driving transistor T_{DR} reaches its threshold voltage V_{TH}, the driving transistor T_{DR} is changed to the on state and the driving potential V_{DR[m]} (potential W(t)) is supplied to the electrophoretic element 40.

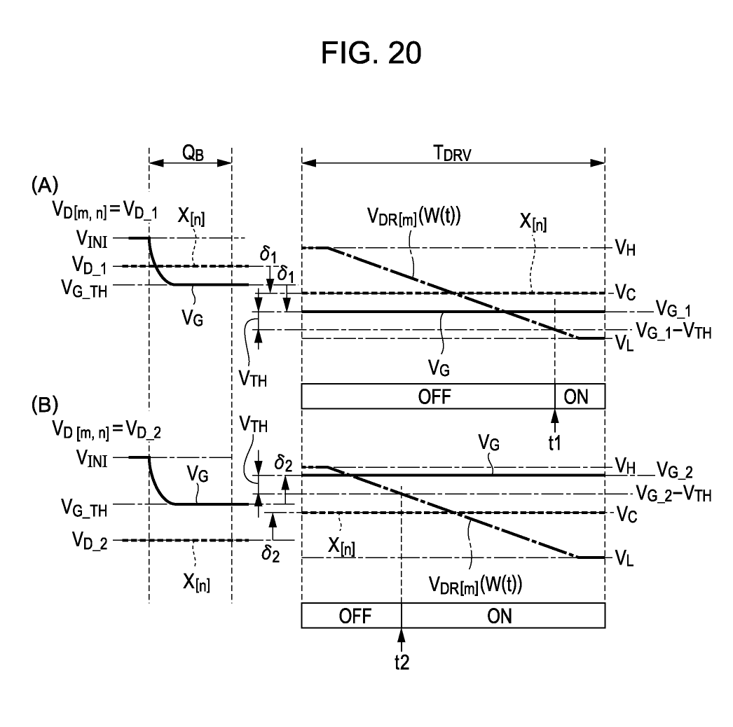

A part (A) and a part (B) of FIG. 20 are schematic diagrams of a change in the potential (dotted line) of the instruction signal X_{[n]}, the potential V_{G} (solid line) of the gate of the driving transistor T_{DR} and the driving potential V_{DR[m]} (chained line) with time. In part (A) of FIG. 20, the case where the gradation potential V_{D[m,n]} is set to the potential V_{D}_{_{—}}₁ (V_{D}_{_{—}}₁>V_{C}) is considered. If the instruction signal X_{[n]} is set to the reference potential V_{C} at the start point of the operation period T_{DRV}, the potential V_{G} of the gate of the driving transistor T_{DR} is changed to a potential V_{G1} lower than the potential V_{G}_{_{—}}_{TH} after setting in the compensation period T_{CMP}, by a difference δ₁ between the gradation potential V_{D}_{_{—}}₁ and the reference potential V_{C}. At a time t1 when the potential W(t) of the driving potential V_{DR[m]} decreases with time so as to reach a potential (V_{G}_{_{—}}₁−V_{TH}) which is less than the potential V_{G-1} by the threshold voltage V_{TH}, the voltage V_{GS} between the gate and the source of the driving transistor T_{DR} reaches the threshold voltage V_{TH} and the driving transistor T_{DR} transitions to the on state.

In contrast, in part (B) of FIG. 20, the case where the gradation potential V_{D[m,n]} is set to a potential V_{D}_{_{—}}₂ (V_{D}_{_{—}}₂<V_{C}) lower than the potential V_{D}_{_{—}}₂ is considered. When the operation period T_{DRV} starts, the potential V_{G} of the gate of the driving transistor T_{DR} is changed to a potential V_{G2} higher than the potential V_{G}_{_{—}}_{TH} set in the compensation period T_{CMP}, by a difference δ₂ between the gradation potential V_{D}_{_{—}}₂ and the reference potential V_{D}. At a time t2 when the potential W(t) of the driving potential V_{DR[m]} is decreased to a potential (V_{G}_{_{—}}₂−V_{TH}) which is less than the potential V_{G-2} by the threshold voltage V_{TH}, the driving transistor T_{DR} transitions to the on state.

As described above, the times t1 and t2 when the driving transistor T_{DR} within the operation period T_{DRV} transitions from the off state to the on state are variably controlled according to the gradation potential V_{D[m,n]}. Accordingly, similarly to the above-described embodiment, the gradation of the electrophoretic element 40 of each pixel circuit P_{IX} is controlled in multiple stages according to the gradation potential V_{D[m,n]} of the pixel circuit P_{IX}. More specifically, as can be understood from the example of FIG. 20, as the gradation potential V_{D[m,n]} is decreased, the length of the time when the driving transistor T_{DR} is in the on state is increased. Accordingly, the gradation of the electrophoretic element 40 is controlled so as to be a low gradation (gradation close to black). Even in the third embodiment, the same effects as the first embodiment are realized.

### E: Fifth Embodiment

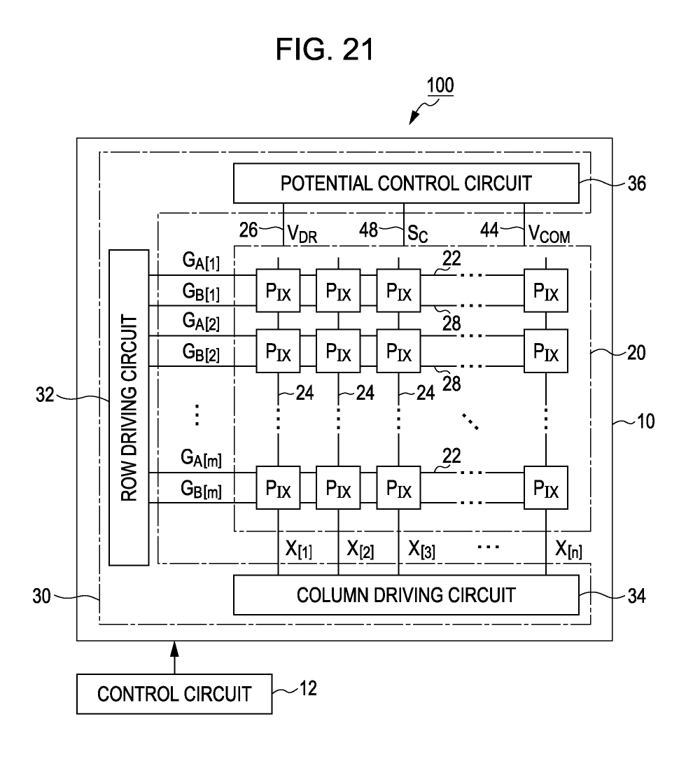

FIG. 21 is a block diagram of an electro-optical device 100 according to a fifth embodiment. As shown in FIG. 21, M control lines 22 and M control lines 28 which are formed in parallel, and N signal lines 24 crossing the control lines 22 and the control lines 28 are formed in a display unit 20 of the electro-optical device 100 of the fifth embodiment. All pixel circuits P_{IX} in the display unit 20 are commonly connected to a driving potential line 26 and a capacitive line 48. A potential control circuit 36 supplies a driving potential V_{DR} to the driving potential line 26 and supplies a capacitive potential S_{C} to the capacitive line 48. That is, the capacitive potential S_{C} and the driving potential V_{DR} are commonly supplied to all pixel circuits P_{IX}.

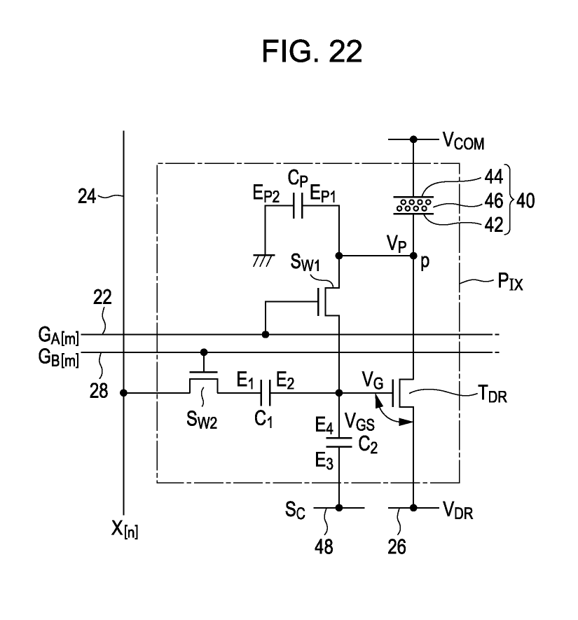

FIG. 22 is a circuit diagram of the pixel circuit P_{IX} of the fifth embodiment. In FIG. 22, one pixel circuit P_{IX} located at an m-th row and an n-th column is representatively shown. As shown in FIG. 22, the pixel circuit P_{IX} has a configuration in which a switch S_{W2} and a capacitive element C₂ are added to the pixel circuit P_{IX} of the first embodiment. The capacitive element C₂ is a capacitor including an electrode E₃ connected to the capacitive line 48 and an electrode E₄ connected to the gate of the driving transistor T_{DR}, similarly to the third embodiment.

The switch S_{W2} includes an N channel type thin film transistor similarly to the driving transistor T_{DR} or the switch S_{W1} and controls electrical connection (electrical connection/non-electrical connection) between the signal line 24 of the n-th column and the electrode E₁ of the capacitive element C₁. The gate of the switch S_{W2} is connected to the control line 22 of the m-th row. As shown in FIGS. 21 and 22, a row driving circuit 32 supplies control signals G_{A[1]} to G_{A[m]} to the control lines 22 and supplies control signals G_{B[1]} to G_{B[m]} to the control lines 28. A configuration in which a circuit for generating the control signals G_{A[1]} to G_{A[m]} and a circuit for generating the control signals G_{B[1]} to G_{B[m]} are separately mounted may be employed. The rest of the configuration of the pixel circuit P_{IX} is the same as that of the first embodiment.

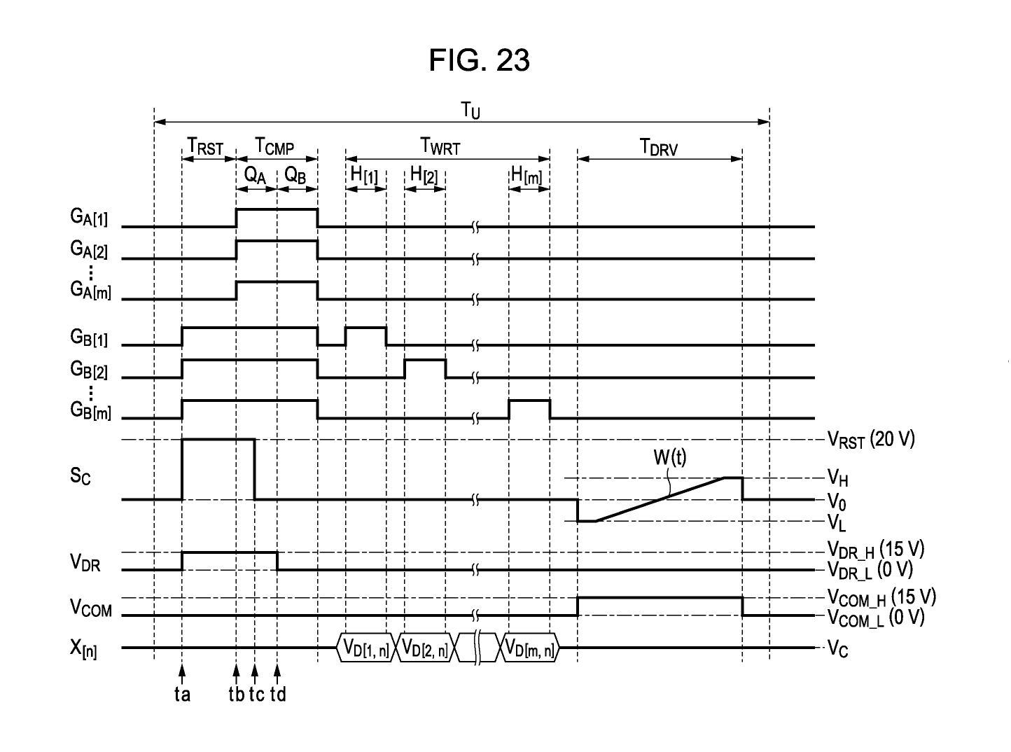

FIG. 23 is an explanatory diagram of an operation of the electro-optical device 100 of the fifth embodiment. As shown in FIG. 23, the unit period T_{U} which is the period of the operation of the electro-optical device 100 includes an initialization period T_{RST}, a compensation period T_{CMP}, a write period T_{WRT} and an operation period T_{DRV}. Similarly to the first embodiment, an initialization operation is executed in parallel with respect to all pixel circuits P_{IX} in the initialization period T_{RST} and a driving operation is executed in parallel with respect to all pixel circuits P_{IX} in the operation period T_{DRV}.

Although the compensation operation is sequentially executed in the row units of the pixel circuit P_{IX} in the first embodiment, the compensation operation is executed in parallel (concurrently) with respect to all pixel circuits P_{IX} in the display unit 20 in the compensation period T_{CMP}, in the fifth embodiment. As shown in FIG. 23, the compensation period T_{CMP}, is divided into a compensation preparation period Q_{A} for setting a potential V_{G} of the gate of the driving transistor T_{DR} to an initial compensation value V_{INI} and a compensation execution period Q_{B} for executing the compensation operation. The write period T_{WRT} is divided into M selection periods (horizontal scanning periods) H_{[1]} to H_{[m]} corresponding to rows of the pixel circuit P_{IX}. In a selection period H_{[m]}, a writing operation (supply of the gradation potential V_{D[m,n]}) is executed with respect to N pixel circuits P_{IX} of the m-th row.

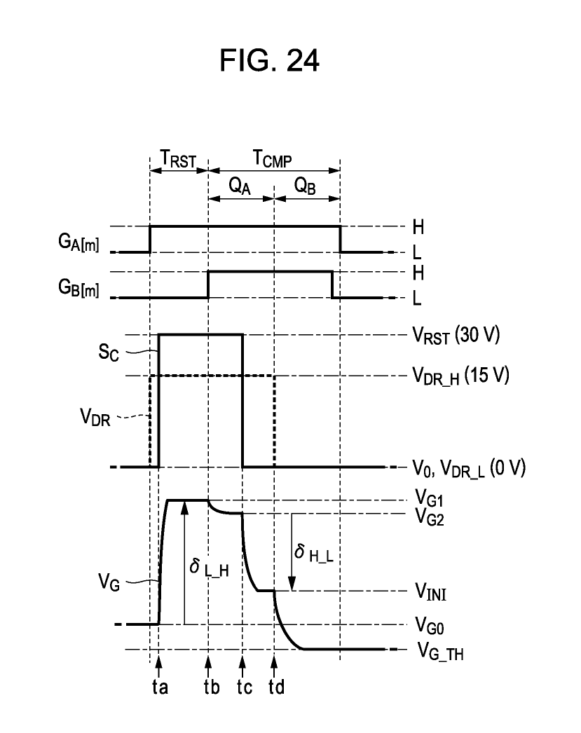

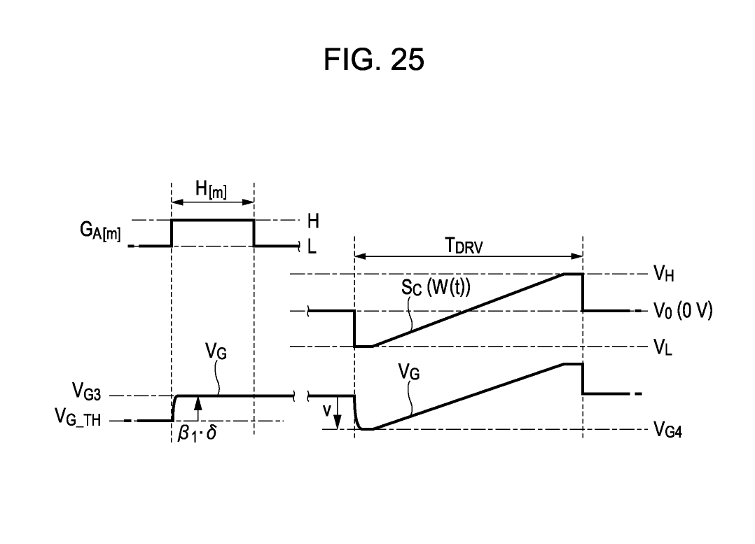

FIG. 24 is an explanatory diagram of the potential V_{G} of the gate of the driving transistor T_{DR} in the initialization period T_{RST} and the compensation period T_{CMP}. FIG. 25 is an explanatory diagram of the potential V_{G} of the gate of the driving transistor T_{DR} in the selection period H_{[m]} and the operation period T_{DRV}. The operations of the above-described periods (T_{RST}, T_{CMP}, T_{WRT} and T_{DRV}) will be described with reference to FIGS. 23 to 25. As shown in FIG. 24, just before the initialization period T_{RST}, the case where the potential V_{G} of the gate of the driving transistor T_{DR} is set to a potential V_{G0} is considered.

### 1. Initialization Period T_{RST}

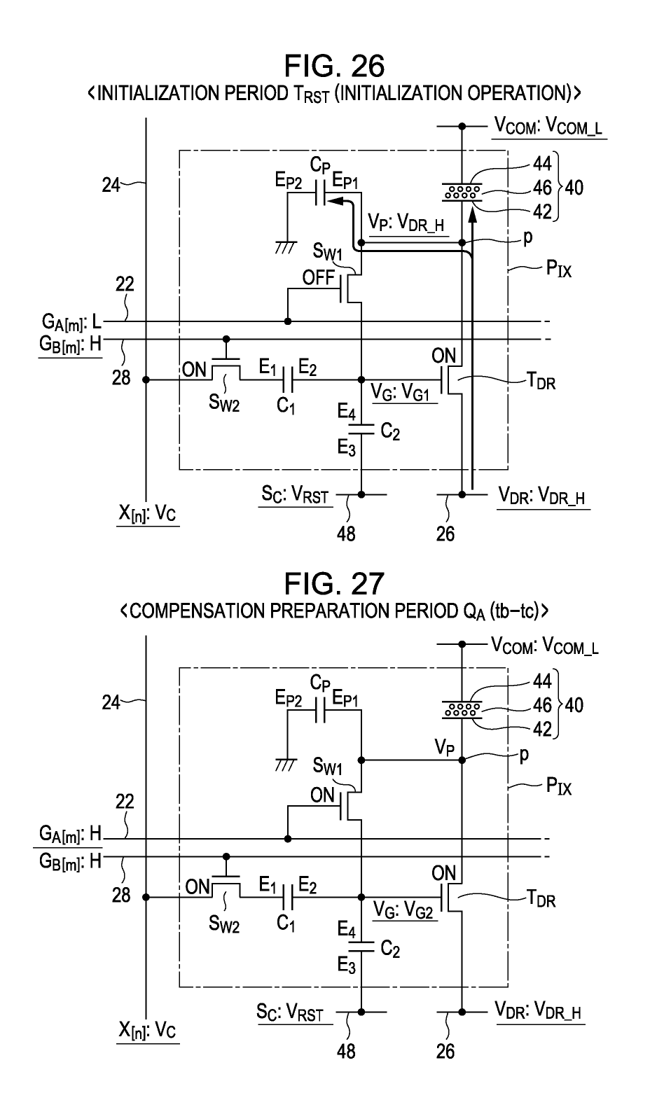

As shown in FIGS. 23 and 26, the column driving circuit 34 sets the instruction signals X_{[1]} to X_{[N]} to the reference potential V_{C} in an initialization period T_{RST}. When the initialization period T_{RST} starts, the row driving circuit 32 sets the control signals G_{B[1]} to G_{B[m]} to a high level so as to control the switch S_{W2} of each of all the pixel circuits P_{IX} to an on state. Accordingly, the reference potential V_{C} of the instruction signal X_{[n]} is supplied from the signal line 24 to the electrode E₁ of the capacitive element C₁ of each pixel circuit P_{IX}. In contrast, the potential control circuit 36 changes the driving potential V_{DR} of the driving potential line 26 from a low-level potential V_{DR}_{_{—}}_{L} to a high-level potential V_{DR}_{_{—}}_{H} and holds a common potential V_{COM} of the counter electrode 44 at a low-level potential V_{COM}_{_{—}}_{L}.

As shown in FIG. 24, if a time ta within the initialization period T_{RST} is reached, the potential control circuit 36 changes the capacitive potential S_{C} of the capacitive line 48 from a potential V₀ (0 V) to the initialization potential V_{RST}. Accordingly, the potential V_{G} of the gate of the driving transistor T_{DR} is increased to the potential V_{G1} in tandem with the capacitive potential S_{C} by capacitive coupling of the capacitive element C₂. In the initialization period T_{RST}, the control signals G_{A[1]} to G_{A[m]} are set to a low level and the additional capacitive element C_{P} is electrically insulated from the gate of the driving transistor T_{DR}. Accordingly, similarly to the third embodiment, a change δ_{L}_{_{—}}_{H} (V_{G1}=V_{G0}+δ_{L}_{_{—}}_{H}) in the potential V_{G} at the time ta of the initialization period T_{RST} becomes a voltage (δ_{L}_{_{—}}_{H}=β2(V_{RST}−V₀), β2=c₂/(c₁+c₂)) obtained by dividing the change (V_{RST}−V₀) of the capacitive potential S_{C} by the capacitive element C₁ and the capacitive element C₂.

The initialization potential V_{RST} of the capacitive potential S_{C} is set to a potential (for example 30V) for enabling the driving transistor T_{DR} to transition to an on state in a state in which the driving potential V_{DR} is set to the high-level potential V_{DR}_{_{—}}_{H}. In the initialization period T_{RST}, the potential V_{P} of the circuit point p is initialized to the high-level potential V_{DR}_{_{—}}_{H} supplied from the driving potential line 26 through the driving transistor T_{DR} (initialization operation), as denoted by an arrow of FIG. 26. That is, the reverse bias is applied to the electrophoretic element 40 and the high-level potential V_{DR}_{_{—}}_{H} is held in the additional capacitive element C_{P}.

### 2. Compensation Period T_{CMP}

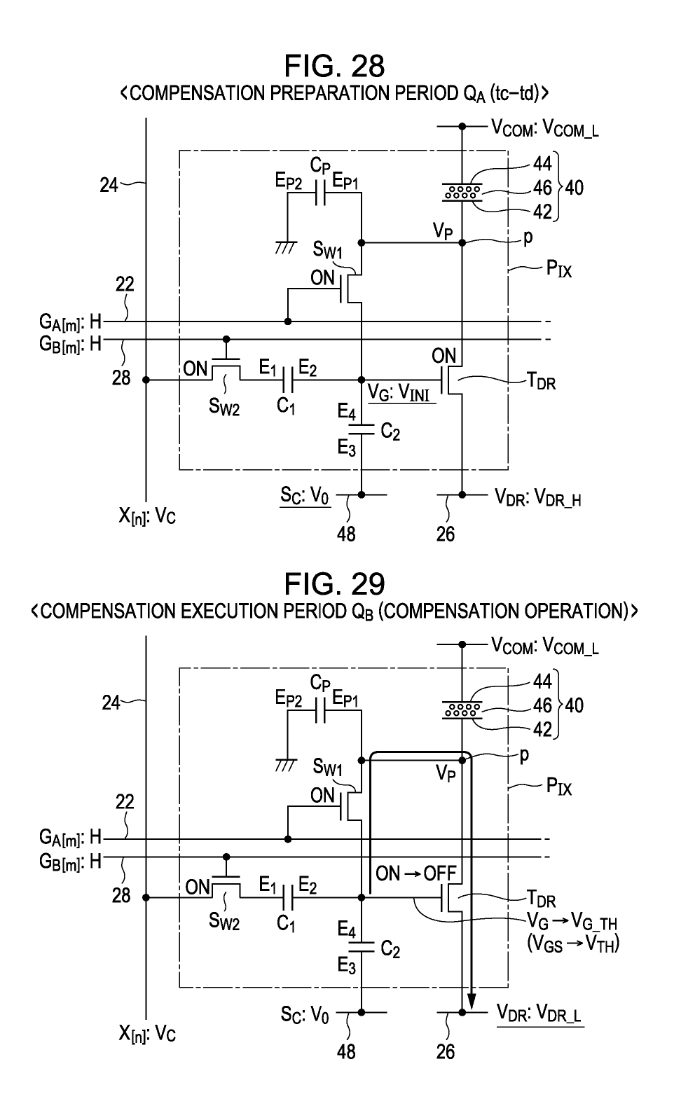

When the compensation preparation period Q_{A} subsequent to the initialization period T_{RST} in the compensation period T_{CMP}, starts (time tb of FIG. 24), the row driving circuit 32 sets the control signals G_{A[1]} to G_{A[m]} to the high level in a state in which the control signals G_{B[1]} to G_{B[m]} are held at the high level so as to control the switch S_{W1} of each pixel circuit P_{IX} to the on state, as shown in FIGS. 23 and 27. That is, the driving transistor T_{DR} of each pixel circuit P_{IX} is diode-connected. Accordingly, as shown in FIG. 24, if the potential V_{G} of the gate of the driving transistor T_{DR} decreases with time so as to reach a potential V_{G2} (V_{G2}=V_{DR R}+V_{TA}) in which the voltage V_{GS} between the gate and the source of the driving transistor T_{DR} becomes a threshold voltage V_{TH}, the driving transistor T_{DR} transitions to the off state.

When a time tc of the compensation preparation period Q_{A} is reached, the potential control circuit 36 decreases the capacitive potential S_{C} from the initialization potential V_{RST} to the potential V₀, as shown in FIGS. 23 and 28. Accordingly, as shown in FIG. 24, the potential V_{G} of the gate of the driving transistor T_{DR} is decreased from the potential V_{G2} to the initial compensation value V_{INI} in tandem with the change in the capacitive potential S_{C}. At the time tc, since the additional capacitive element C_{P} is connected to the gate of the driving transistor T_{DR}, the change δ_{H}_{_{—}}_{L} (V_{INI}=V_{G2}−δ_{H}_{_{—}}_{L}) of the potential V_{G} at the time tc becomes a voltage (δhd H_{_{—}}_{L}=γ2 (V_{RST}−V₀), γ2=c₂/(c₁+c₂+c_{P})) obtained by dividing the change (V_{RST}−V₀) of the capacitive potential S_{C} by the capacitive element C₁, the capacitive element C₂ and the additional capacitive element C_{P}, similarly to the third embodiment. That is, the change δ_{H}_{_{—}}_{L} of the potential V_{G} at the time tc is less than the change δ_{TH} of the potential V_{G} at the time ta. Using the above-described difference between the change δ_{H}_{_{—}}_{L} and the change δ_{L}_{_{—}}_{H}, the initial compensation value V_{INI} is set to a potential exceeding the potential V_{G0} of the gate before the start of the initialization period T_{RST}, similarly to the first embodiment.

When the compensation execution period Q_{B} starts (time td of FIG. 24), the potential control circuit 36 changes the driving potential V_{DR} from the high-level potential V_{DR}_{_{—}}_{H} to the low-level potential V_{DR}_{_{—}}_{L}. In the compensation execution period Q_{B}, the on state of the switch S_{W1} (diode connection of the driving transistor T_{DR}) is held from the compensation preparation period Q_{A}. Accordingly, when the driving potential V_{DR} (the potential of the source of the driving transistor T_{DR}) is decreased to the low-level potential V_{DR}_{_{—}}_{L} such that the driving transistor T_{DR} transitions to the on state, as denoted by an arrow of FIG. 29, the charges of the gate of the driving transistor T_{DR} are discharged to the driving potential line 26 through the switch S_{W1}, the circuit point p and the driving transistor T_{DR}. Accordingly, the potential V_{G} of the gate is decreased from the initial compensation value V_{INI} with time and the driving transistor T_{DR} transitions to the off state (compensation operation) at a time when the voltage V_{GS} between the gate and the source reaches the threshold voltage V_{TH}.

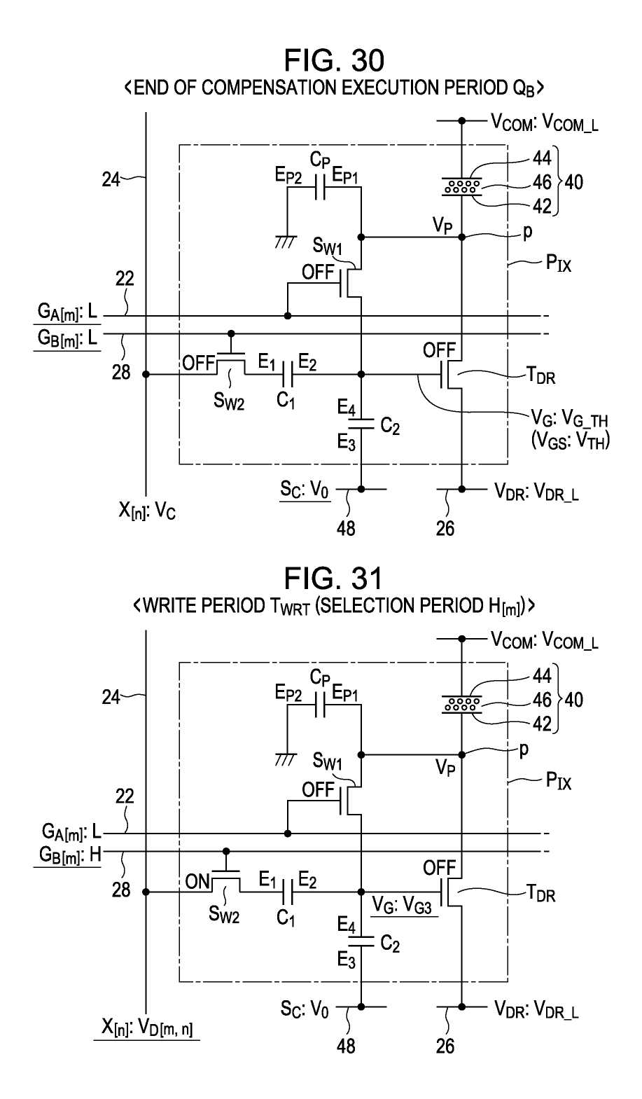

When the compensation execution period Q_{B} finishes, the row driving circuit 32 changes the control signals G_{A[1]} to G_{A[m]} and the control signals G_{B[1]} to G_{B[m]} to a low level so as to control the switch S_{W1} and switch S_{W2} of each pixel circuit P_{IX} to the off state, as shown in FIGS. 23 and 30. Accordingly, at an end point of the compensation period T_{CMP}, as shown in FIG. 30, in all the pixel circuits P_{IX} in the display unit 20, in a state in which the electrode E₁ of the capacitive element C₁ is set to the reference potential V_{C}, the potential V_{G} of the gate of the driving transistor T_{DR} is set to a potential V_{G}_{_{—}}_{TH} (V_{G}_{_{—}}_{TH}−V_{DR}_{_{—}}_{L}−V_{TH}).

### 3. Write Period T_{WRT}

As shown in FIGS. 23 and 31, the row driving circuit 32 sequentially sets the control signals G_{B[1]} to G_{B[m]} to the high level in the selection periods H_{[1]} to H_{[m]} within the write period T_{WRT}. The control signals G_{A[1]} to G_{A[m]} are held at the low level. In the selection period H_{[m]} in which the control signal G_{B[m]} is set to the high level, the switch S_{W2} of each of the N pixel circuits P_{IX} of the m-th row transitions to the on state. In contrast, the column driving circuit 34 sets the instruction signals X_{[n]} of each signal line 24 to the gradation potential V_{D[m,n]} in the selection period H_{[m]}. Accordingly, as shown in FIG. 31, the potential of the electrode E₁ of the capacitive element C₁ in each pixel circuit P_{IX} of the m-th row is changed from the reference potential V_{C} after setting in the compensation period T_{CMP} to the gradation potential V_{D[m,n].}

If the potential of the electrode E₁ is changed by the change δ (δ=V_{D[m,n]}−V_{C}) in the selection period H_{[m]}, as shown in FIGS. 25 and 31, the potential V_{G} of the gate of the driving transistor T_{DR} is changed to a potential V_{G3} by capacitive coupling of the capacitive element C₁. The potential V_{G3} is set to a potential (V_{G3}=V_{G}_{_{—}}_{TH}+β1·δ, β1=c1/(c₁+c₂)) changed from the potential V_{G}_{_{—}}_{TH} after setting in the compensation period T_{CMP}, by a voltage obtained by dividing the change δ in the potential of the electrode E₁ by the capacitive element C₁ and the capacitive element C₂. When the selection period H_{[m]} finishes, the control signal G_{B[m]} is set to the low level such that the switch S_{W2} of each pixel circuit P_{IX} of the m-th row transitions to the off state. The above-described writing operation is sequentially executed in row units in each selection period H_{[m].}

### 4. Operation Period T_{DRV}

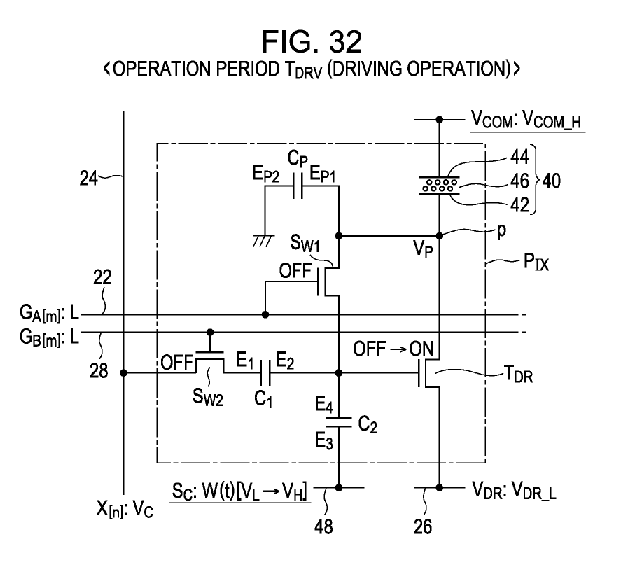

When the operation period T_{DRV} after the elapse of the write period T_{WRT} starts, the potential control circuit 36 changes the common potential V_{COM} of the counter electrode 44 to the high-level potential V_{COM}_{_{—}}_{H}, in a state in which the driving potential V_{DR} of the driving potential line 26 is held at the low-level potential V_{DR}_{_{—}}_{L}, as shown in FIGS. 23 and 32. In contrast, in the operation period T_{DRV}, the control signals G_{A[1]} to G_{A[m]} and the control signals G_{B[1]} to G_{B[m]} are set to the low level such that the switch S_{W1} and the switch S_{W2} of each pixel circuit P_{IX} are held in the off state, as shown in FIG. 32.

The potential control circuit 36 sets the capacitive potential S_{C} supplied to the capacitive line 48 to the potential W(t). As shown in FIGS. 23 and 25, the potential W(t) is controlled to a ramp waveform (a saw-like wave) linearly changed from the potential V_{L} to the potential V_{H} from the start point to the end point of the operation period T_{DRV}. More specifically, the potential control circuit 36 decreases the potential W(t) from the potential V₀ to the potential V_{L} at the start point of the operation period T_{DRV} and changes the potential W(t) such that the potential V₀ becomes a central value (amplitude center of the potential W(t)) between the potential V_{L} and the potential V_{H}.

The potential V_{G} of the gate of the driving transistor T_{DR} is increased with time in tandem with the capacitive potential S_{C} (potential W(t)) by capacitive coupling of the capacitive element C₂. First, if the potential W(t) is changed from the potential V₀ to the potential V_{L} at the start point of the operation period T_{DRV}, the potential V_{G} of the gate of the driving transistor T_{DR} is changed (decreased) by a change v from the potential V_{G3} after setting in the selection period H_{[m]} to the potential V_{G4}, as shown in FIG. 25. The change v is a fixed value (v=β2(V₀−V_{L}), β2=c₂/(c₁+c₂)) obtained by driving the change amount (V₀−V_{L}) of the potential W(t) by the capacitive element C₁ and the capacitive element C₂.

As shown in FIG. 25, the potential V_{G} of the gate of the driving transistor T_{DR} is changed with time from the potential V_{G4} in tandem with the change (V_{L}→V_{H}) of the potential W(t) and, at a time when reaching the potential V_{G}_{_{—}}_{TH}, the voltage V_{GS} between the gate and the source of the driving transistor T_{DR} reaches its threshold voltage V_{TH} and the driving transistor T_{DR} transitions to the on state. Since the potential V_{G4} at the start point of the operation period T_{DRV} depends on the potential V_{G3} set according to the gradation potential V_{D[m,n]} in the selection period H_{[m]}, the driving transistor T_{DR} of the pixel circuit P_{IX} located at the m-th row and the n-th column transitions from the off state to the on state at a variable time according to the designated gradation (gradation potential V_{D[m,n]}) of the pixel circuit P_{IX} in the operation period T_{DRV}. The behavior of the electrophoretic element 40 when the driving transistor T_{DR} transitions to the on state is equal to that of the first embodiment.

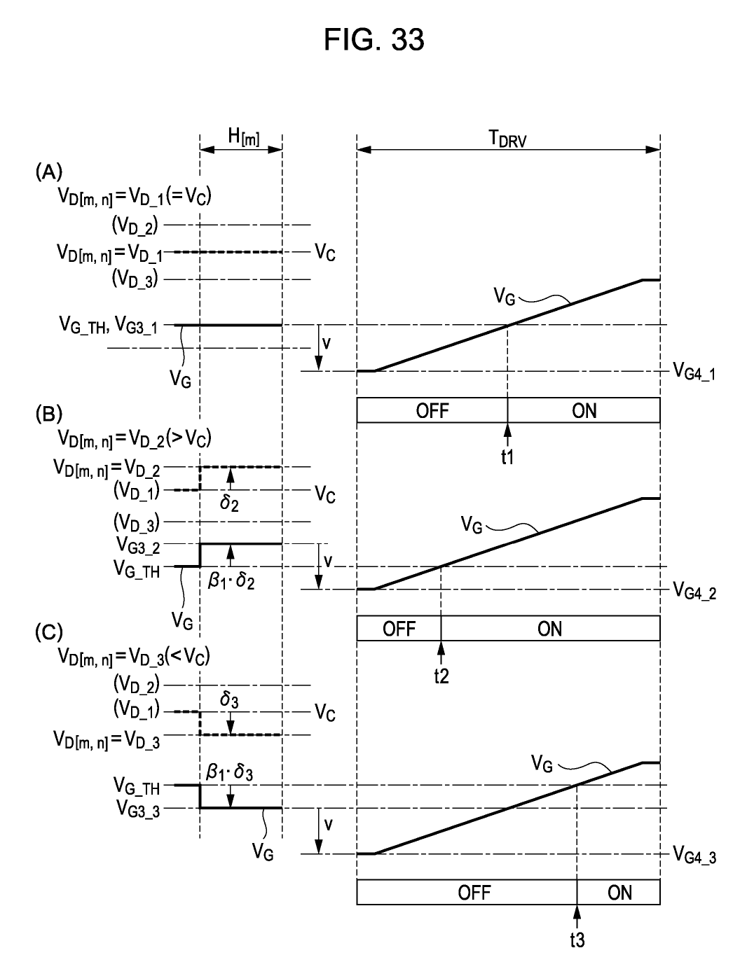

FIG. 33 is a schematic diagram showing a state in which the times t1, t2 and t3 when the driving transistor T_{DR} transitions from the off state to the on state is changed according to the gradation potential V_{D[m,n]}. The change in potential of the electrode E₁ in the selection period H_{[m]} is denoted by a dotted line and the change in potential V_{G} of the gate of the driving transistor T_{DR} in the selection period H_{[m]} and the operation period T_{DRV} is denoted by a solid line.

In a part (A) of FIG. 33, the case where the gradation potential V_{D[m,n]} is set to a potential V_{D}_{_{—}}₁ is considered. The potential V_{DT} is equal to the reference potential V_{C}. Accordingly, the potential V_{G} of the gate of the driving transistor T_{DR} is not changed in the selection period H_{[m]}. That is, the potential V_{G3}_{_{—}}₂ at the end point of the selection period H_{[m]} is held at the same potential as the potential V_{G}_{_{—}}_{TH} after setting in the compensation period T_{CMP}. When the operation period T_{DRV} starts, the potential V_{G} is increased with time from the potential V_{G4-1} which is less than the potential V_{G3}_{_{—}}₁ by the voltage v. At a time t1 when the potential V_{G} reaches the potential V_{G}_{_{—}}_{TH} (=V_{G3}_{_{—}}₁), the driving transistor T_{DR} transitions from the off state to the on state.

In a part (B) of FIG. 33, the case where the gradation potential V_{D[m,n]} is set to a potential V_{D}_{_{—}}₂ higher than the reference potential V_{C} (V_{D}_{_{—}}₁) is considered. If the instruction signal X_{[n]} is increased from the reference potential V_{C} to the gradation potential V_{D}_{_{—}}₂ in the selection period the potential V_{G} of the gate of the driving transistor T_{DR} is increased to a potential V_{G3}_{_{—}}₂ (V_{G3}_{_{—}}₂=V_{G}_{_{—}}_{TH}+β1·δ2) according to the change δ2 (δ2=V_{D}_{_{—}}₂−V_{C}) in the potential of the instruction signal X_{[n]}. The potential V_{G4}_{_{—}}₂ obtained by decreasing the potential V_{G3}_{_{—}}₂ by the change v at the start point of the operation period T_{DRV} exceeds the potential V_{G4}_{_{—}}₁ of the part (A) of FIG. 33. Accordingly, the driving transistor T_{DR} transitions to the on state at a time t2 earlier than the time t1 of the part (A) of FIG. 33.

In a part (C) of FIG. 33, the case where the gradation potential V_{D[m,n]} is set to a potential V_{D}_{_{—}}₃ lower than the reference potential V_{C} (V_{D}_{_{—}}₁) is considered. Since the potential V_{G} of the gate of the driving transistor T_{DR} is decreased to a potential V_{G3}_{_{—}}₃ (V_{G3}_{_{—}}₃=V_{G}_{_{—}}_{TH}+β1·δ3) according to the change δ3 (δ3=V_{D}_{_{—}}₃−V_{C}<0) in the potential of the instruction signal X_{[n]} in the selection period H_{[m]}, the potential V_{G4}_{_{—}}₃ (V_{G4}_{_{—}}₃=V_{G3}_{_{—}}₃−v) at the start point of the operation period T_{DRV} falls short of the potential V_{G4}_{_{—}}₁ of the part (A) of FIG. 33. Accordingly, the driving transistor T_{DR} transitions to the on state at a time t3 later than the time t1 of the part (A) of FIG. 13.

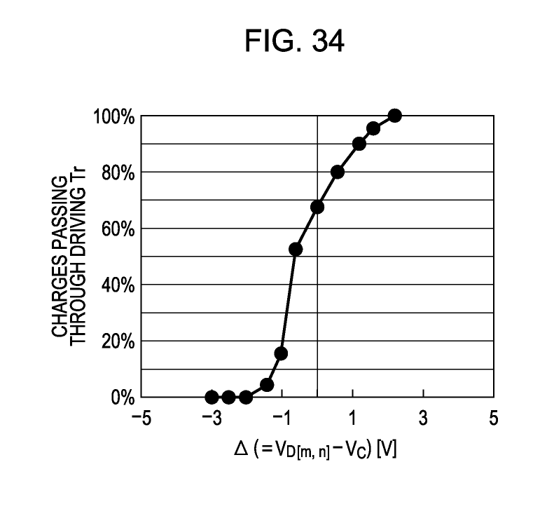

FIG. 34 is a graph of a relationship between a difference Δ (Δ=V_{D[m,n]} −V_{C}) between the gradation potential V_{D[m,n]} and the reference potential V_{C} and a total amount of charges passing through the driving transistor T_{DR} within the operation period T_{DRV}, similarly to FIG. 14. As can be understood from FIGS. 33 and 34, in the fifth embodiment, contrary to the first embodiment (FIG. 14), as the gradation potential V_{D[m,n]} is increased (as the difference Δ with the reference potential V_{C} is increased), a time when the driving transistor T_{DR} transitions to the on state in the operation period T_{DRV} is increased. Accordingly, as the gradation potential V_{D[m,n]} is increased (as the length of the time when the driving transistor T_{DR} transitions to the on state within the operation period T_{DRV}), the gradation of the electrophoretic element 40 is controlled to a low gradation (gradation close to black).

Even in the above-described fifth embodiment, the same effects as the first embodiment are realized. In the fifth embodiment, since the compensation operation is executed in parallel with respect to all pixel circuits P_{IX} in the display unit 20 in the compensation period T_{CMP}, as compared to the first embodiment in which the compensation operation is executed in row units, it is possible to shorten a time required for the compensation operation of each pixel circuit P_{IX}. In order to enable the voltage V_{GS} between the gate and the source of the driving transistor T_{DR} to sufficiently approach or coincide with the threshold voltage V_{TH} in the compensation operation, a longer time is necessary as compared to the writing operation. Accordingly, according to the fifth embodiment in which the compensation operation is executed in parallel with respect to all pixel circuits P_{IX}, it is possible to shorten the unit period T_{U} as compared to the first embodiment.

Since the switch S_{W2} is interposed between the capacitive element C₁ of each pixel circuit P_{IX} and the signal line 24, as compared to the configuration in which the capacitive element C₁ is directly connected to the signal line 24, it is possible to reduce the capacitive component pertaining to the signal line 24. Accordingly, it is possible to reduce power wasted in charging/discharging of the signal line 24. In contrast, according to the first embodiment, since the total number (2) of transistors of each pixel circuit P_{IX} is reduced as compared to the number (3) of transistors in the fifth embodiment, the configuration of the pixel circuit P_{IX} is simplified (further, high accuracy is realized). Since the waveforms of the control signals G_{A[1]} to G_{A[m]} of the fifth embodiment are common, a configuration in which a common control signal G_{A} is supplied to each pixel circuit P_{IX} may be employed.

### F: Sixth Embodiment

In the fifth embodiment, similarly to the second embodiment or the third embodiment, the initial compensation value V_{INI} is set in the compensation preparation period Q_{A} using the difference (δ_{L}_{_{—}}_{H}>δ_{H}_{_{—}}_{L}) between the increase amount δ_{L}_{_{—}}_{H} and the decrease amount δ_{H}_{_{—}}_{L} of the potential V_{G}. In the sixth embodiment, the method of the first embodiment in which the potential V_{G} is set to the initial compensation value V_{INI} using the charges accumulated in the additional capacitive element C_{P} in the initialization period T_{RST} is applied to the setting of the initial compensation value V_{INI} of the fifth embodiment. The configuration of the pixel circuit P_{IX} is equal to that of the fifth embodiment.

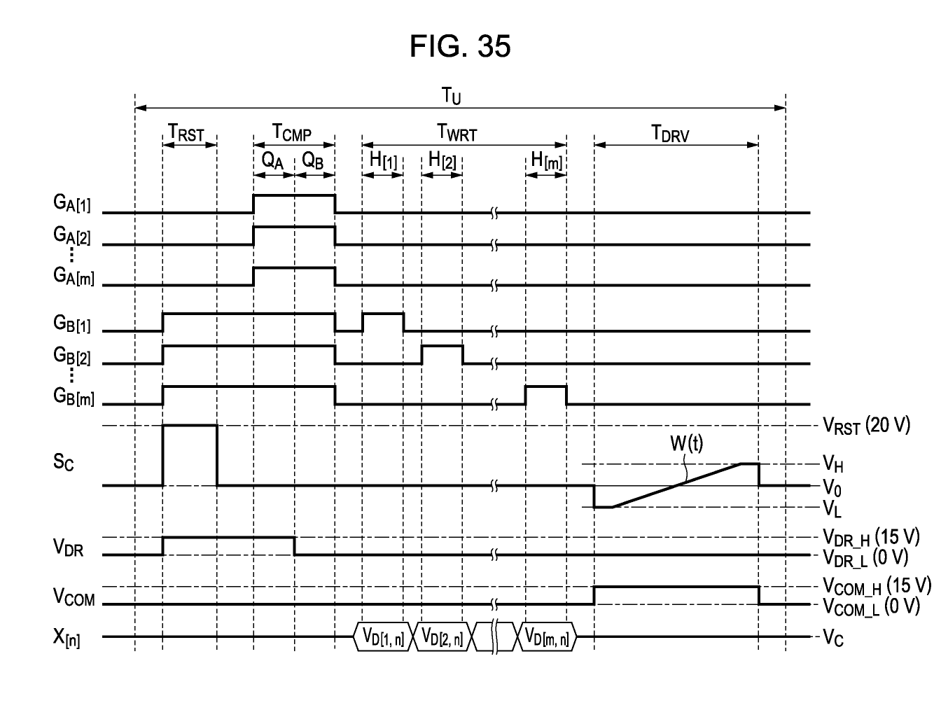

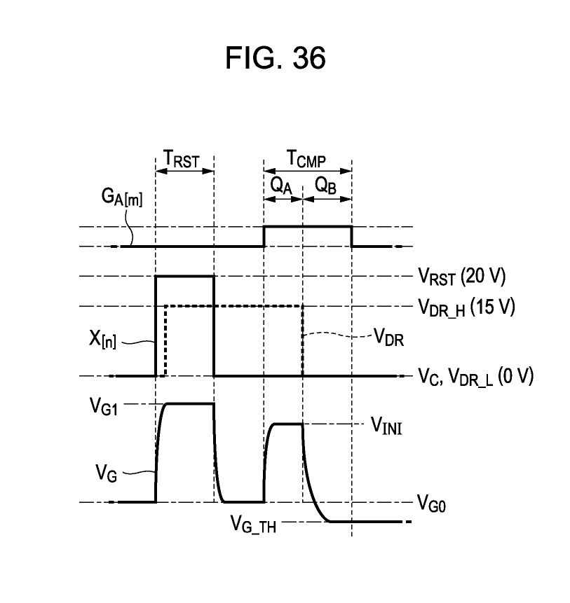

FIG. 35 is an explanatory diagram of an operation of an electro-optical device 100 according to a sixth embodiment. FIG. 36 is a schematic diagram showing transition of the potential V_{G} of the gate of the driving transistor T_{DR} in the initialization period T_{RST} and the compensation period T_{CMP}. Similarly to the fifth embodiment, the potential control circuit 36 sets the capacitive potential S_{C} to the initialization potential V_{RST} in the initialization period T_{RST} and sets the driving potential V_{DR} to the high-level potential V_{DR}_{_{—}}_{H} so as to initialize the potential V_{P} of the circuit point p to the high-level potential V_{DR}_{_{—}}_{H}. If the end point of the initialization period T_{RST} is reached, the potential control circuit 36 changes the capacitive potential S_{C} from the initialization potential V_{RST} to the potential V₀, as shown in FIGS. 35 and 36. Accordingly, the potential V_{G} of the gate of the driving transistor T_{DR} is changed to the potential V_{G0} before the start of the initialization period T_{RST}.

When the compensation preparation period Q_{A} of the compensation period T_{CMP}) starts after the initialization period T_{RST} finishes, the row driving circuit 32 sets the control signals G_{A[1]} to G_{A[m]} to the high level so as to control the switch S_{W1} of each of all pixel circuits P_{IX} to the on state, as shown in FIGS. 35 and 36. Accordingly, the charges accumulated in the additional capacitive element C_{P} are moved to the gate of the driving transistor T_{DR} through the switch S_{W1} in the initialization period T_{RST} and the potential V_{G} of the gate of the driving transistor T_{DR} is changed to the initial compensation value V_{INI} exceeding the preceding potential V_{G0}. More specifically, the initial compensation value V_{INI} is expressed by Equation 2 including a coefficient γp (γp=c_{P}/(c₁+c₂+c_{P})) according to the capacitance value c₁ of the capacitive element C₁, the capacitance value c₂ of the capacitive element C₂, and the capacitance value c_{P} of the capacitive element C_{P}.

V_{INI}=γp·V_{DR}_{_{—}}_{H}+(1−γp)V_{G2} (2)

In the compensation execution period Q_{B} after the elapse of the compensation preparation period Q_{A}, similarly to the fifth embodiment, the driving potential V_{DR} is changed from the high-level potential V_{DR}_{_{—}}_{H} to the low-level potential V_{DR}_{_{—}}_{L} so as to execute the compensation operation. The operations in the write period T_{WRT} and the operation period T_{DRV} are equal to those of the fifth embodiment. Even in the sixth embodiment, the same effects as the fifth embodiment are realized.

### G: Seventh Embodiment

In the above-described embodiments, the forward bias (positive polarity voltage) is applied to the electrophoretic element 40 in the operation period T_{DRV} and the reverse bias (negative polarity voltage) is applied to the electrophoretic element 40 in the initialization period T_{RST}. Accordingly, when comparing with a configuration in which the reverse bias is not applied within the unit period T_{U} (for example, a configuration in which the common potential V_{COM} is held at the high-level potential V_{COM}_{_{—}}_{H}) in the initialization period T_{RST}, it is possible to suppress the application of the DC component to the electrophoretic element 40. Since the time when the forward bias is applied and the time (initialization period T_{RST}) when the reverse bias is applied are different, it is difficult to completely prevent the application of the DC component to the electrophoretic element 40. In the seventh embodiment, the DC component is prevented from being applied by appropriately selecting the gradation potential V_{D[m,n]} with respect to a plurality of unit periods T_{U} of the case of changing a display image.

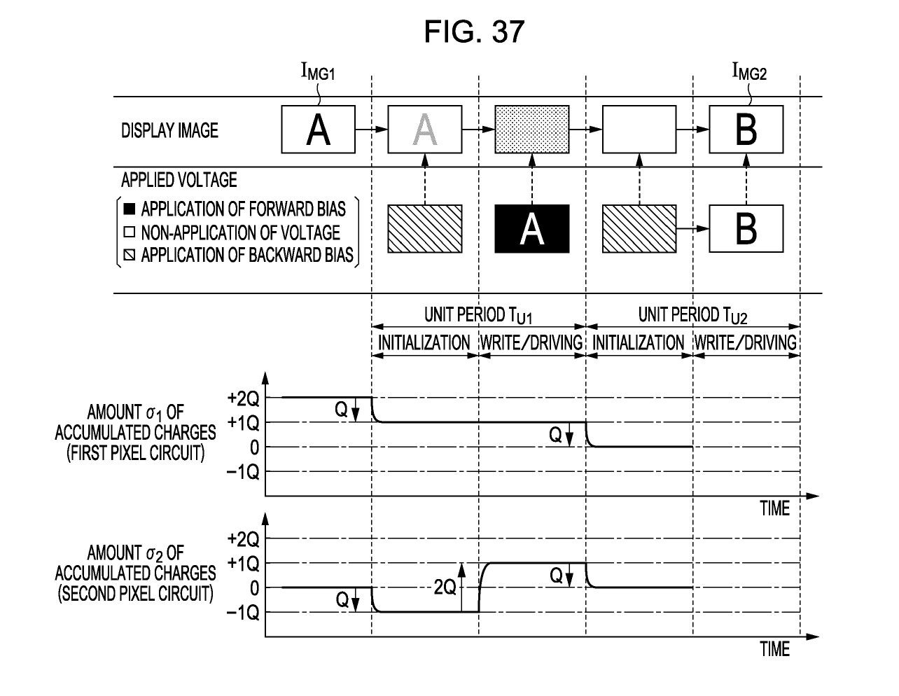

FIG. 37 is an explanatory diagram of an operation of an electro-optical device 100 of the seventh embodiment. As shown in FIG. 37, the case where the display image of the display unit 20 is changed from an image I_{MG1} to an image I_{MG2} is considered. The image I_{MG1} is a still image in which a black character “A” is arranged in a white background and the image I_{MG2} is a still image in which a black character “B” is arranged in a white background. The image I_{MG1} is changed to the image I_{MG2} through a unit period T_{U1} and a unit period T_{U2} from a state in which the image I_{MG1} is displayed.

In FIG. 37, temporal transition of the amount σ of charges (hereinafter, referred to as the “amount of accumulated charge”) accumulated in the electrophoretic element 40 of each pixel circuit P_{IX} is shown. The amount σ₁ of accumulated charges of FIG. 37 refers to the amount of charges accumulated in the electrophoretic element 40 of each pixel circuit (hereinafter, referred to as a “first pixel circuit”) corresponding to a black pixel configuring the character “A” of the image I_{MG1} among the plurality of pixel circuits P_{IX} within the display unit 20. In contrast, the amount σ₂ of accumulated charges refers to the amount of charges accumulated in the electrophoretic element 40 of each pixel circuit (hereinafter, referred to as a “second pixel circuit”) P_{IX} corresponding to a white pixel configuring the background of the image I_{MG1} among the plurality of pixel circuits P_{IX} within the display unit 20. As the amount σ (σ₁, σ₂) of accumulated charge is increased to a positive polarity side, the display gradation of the electrophoretic element 40 transitions to a black side.

In FIG. 37, the voltage applied to the electrophoretic element 40 of each pixel circuit P_{IX} is schematically shown. In the operation period T_{DRV}, the forward bias is applied to the electrophoretic element 40 of the pixel circuit P_{IX} in which black is designated and the voltage is not applied to the electrophoretic element 40 of the pixel circuit P_{IX} in which white is designated (that is, the driving transistor T_{DR} does not transition to the on state). In contrast, in the initialization period T_{RST}, the reverse bias is uniformly applied to the electrophoretic element 40 of each of all pixel circuits P_{IX}. When the forward bias is applied, charges of +2Q are supplied to the electrophoretic element 40 and a display gradation transitions to a black side and, when the reverse bias is applied, charges of Q are eliminated from the electrophoretic element 40 and a display gradation transitions to a white side. In the case where the voltage is not applied (non-application of the voltage), charge movement (change in the amount of accumulated charges G) does not occur. As shown in FIG. 37, in a state in which the image I_{MG1} is displayed (before the start of the unit period T_{U1}), the amount σ₁ of accumulated charges of the electrophoretic element 40 of the first pixel circuit P_{IX} (black) is +2Q and the amount σ₂ of accumulated charges of the electrophoretic element 40 of the second pixel circuit P_{IX} (white) is zero.

In the initialization operation within the unit period T_{U1}, the reverse bias is applied to the electrophoretic element 40 of each of all pixel circuits P_{IX}. As shown in FIG. 37, the amount σ₁ of accumulated charges of the first pixel circuit P_{IX} is reduced from +2Q by Q and is changed to +1Q by applying the reverse bias. Accordingly, the gradation of the electrophoretic element 40 of each first pixel circuit P_{IX} becomes a middle tone (gray) transitioning from black to the white side by the decrease of charges Q. The amount σ₂ of accumulated charges of the second pixel circuit P_{IX} is reduced from zero by Q and is changed to −1Q by applying the reverse bias, but the gradation of the electrophoretic element 40 already reaches white (maximum gradation). Thus, even when the amount σ₂ of accumulated charges is reduced, the gradation of the electrophoretic element 40 is barely changed (overwriting).

In the writing operation within the unit period T_{U1}, the control circuit 12 designates the white gradation to each first pixel circuit P_{IX} for displaying the black pixel of the image I_{MG1} and designates the black gradation to each second pixel circuit P_{IX} for displaying the white pixel of the image I_{MG1}. Accordingly, in the driving operation (operation period T_{DRV}) within the unit period T_{U1}, as shown in FIG. 37, the voltage is not applied to the electrophoretic element 40 of the first pixel circuit P_{IX} and the forward bias is applied to the electrophoretic element 40 of the second pixel circuit P_{IX}. That is, the amount σ₁ of accumulated charges of the first pixel circuit P_{IX} is held at +1Q after applying the reverse bias and the amount σ₂ of accumulated charges of the second pixel circuit P_{IX} is increased from −1Q after applying the reverse bias in the initialization period T_{RST} by 2Q and is changed to +1Q by applying the forward bias. As described above, by the application of the reverse bias in the initialization period T_{RST} of the unit period T_{U1} and the application of the voltage in the operation period T_{DRV} (application of the forward bias/non-application of the voltage), the amount σ₁ of accumulated charges of the first pixel circuit P_{IX} and the amount σ₂ of accumulated charges of the second pixel circuit P_{IX} coincide with each other (σ₁=σ₂=+1Q). As shown in FIG. 37, the gradation of the electrophoretic element 40 becomes a middle tone (gray) corresponding to the amount +1Q of charges in both the first pixel circuit P_{IX} and the second pixel circuit P_{IX}.

Even in the initialization operation (initialization period T_{RST}) of the unit period T_{U2}, similarly to the unit period T_{U1}, since the reverse bias is applied to the electrophoretic element 40 of each of all pixel circuits P_{IX}, the charges of Q are eliminated from the electrophoretic element 40 in both the first pixel circuit P_{IX} and the second pixel circuit P_{IX}. Accordingly, as shown in FIG. 37, both the amount σ₁ of accumulated charges and the amount σ₂ of accumulated charges are changed from +1Q to zero and the gradations of all electrophoretic elements 40 within the display unit 20 are controlled to white. That is, the application of the DC component to the electrophoretic element 40 is solved in both the first pixel circuit P_{IX} and the second pixel circuit P_{IX}. In the writing operation of the unit period T_{U2}, the control circuit 12 designates the gradation of each pixel of the image I_{MG2} to each pixel circuit P_{IX}. Accordingly, the display image of the display unit 20 is changed from the image I_{MG1} to the image I_{MG2}.

According to the above-described seventh embodiment, in spite of the configuration in which only the forward bias is applied to the electrophoretic element 40 in the operation period T_{DRV} and the reverse bias is uniformly applied to the electrophoretic elements 40 of all the pixel circuits P_{IX} in the initialization period T_{RST}, it is possible to efficiently prevent the DC component from being applied to the electrophoretic element 40. Accordingly, it is possible to efficiently prevent deterioration of the electrophoretic element 40 due to the application of the DC component.

Although the white gradation is designated to each first pixel circuit P_{IX} for displaying the black pixel of the image I_{MG1} and the black gradation is designated to each second pixel circuit P_{IX} for displaying the white pixel of the image I_{MG1} in the writing operation within the unit period T_{U1} in the above description, the image I_{MG1} is not limited to binary images of white and black. For example, even when the image I_{MG1} includes a middle tone, the above embodiments are equally applied. In the case of including a first gradation and a second gradation (irrespective of presence/absence of other gradation) in which the image I_{MG1} before change is different is assumed, the writing operation within the unit period T_{U1} is included as an operation for supplying the gradation potential V_{D[m,n]} according to the first gradation to each first pixel circuit P_{IX} for displaying the pixel of the first gradation of the image I_{MG1} and supplying the gradation potential V_{D[m,n]} according to the second gradation to each second pixel circuit P_{IX} for displaying the pixel of the second gradation of the image I_{MG1}. In the above expression, the complementary gradation of the first gradation is suitable as the “gradation according to the first gradation”. Similarly, the complementary gradation of the second gradation is suitable as the “gradation according to the second gradation”. The “complementary gradation” refers to a gradation in which a luminance difference from a central value (that is, a middle luminance between a maximum luminance and a minimum luminance) between white and black is equal. For example, when focusing upon four kinds of gradations including white, slightly gray (light gray), charcoal (dark gray) and black, a relationship between white and black or a relationship between slightly gray and charcoal corresponds to the complementary gradation. According to the above configuration, even in the case where the image I_{MG1} includes a middle tone, it is possible to suit the gradation of the electrophoretic element 40 of both the first pixel circuit P_{IX} and the second pixel circuit P_{IX} to a middle tone corresponding to the amount +1Q of charges.

### H: Modified Example

The above embodiments may be variously modified. Now, the detailed modified examples will be described. Two or more examples which are arbitrarily selected from the following examples may be appropriately combined.

### 1. Modified Example 1

Although the configuration (hereinafter, referred to as “configuration A”) in which the driving transistor T_{DR} is changed from the off state to the on state at a time according to the designated gradation within the operation period T_{DRV} is described in the above embodiments, a configuration (hereinafter, referred to as “configuration B”) in which the driving transistor T_{DR} is changed from the on state to the off state at a time according to the designated gradation within the operation period T_{DRV} may be employed. According to configuration A employed in the above-described embodiment, as described in detail below, it is possible to shorten a time when a user actually recognizes the content of the display image from start of the operation period T_{DRV}, as compared to configuration B.

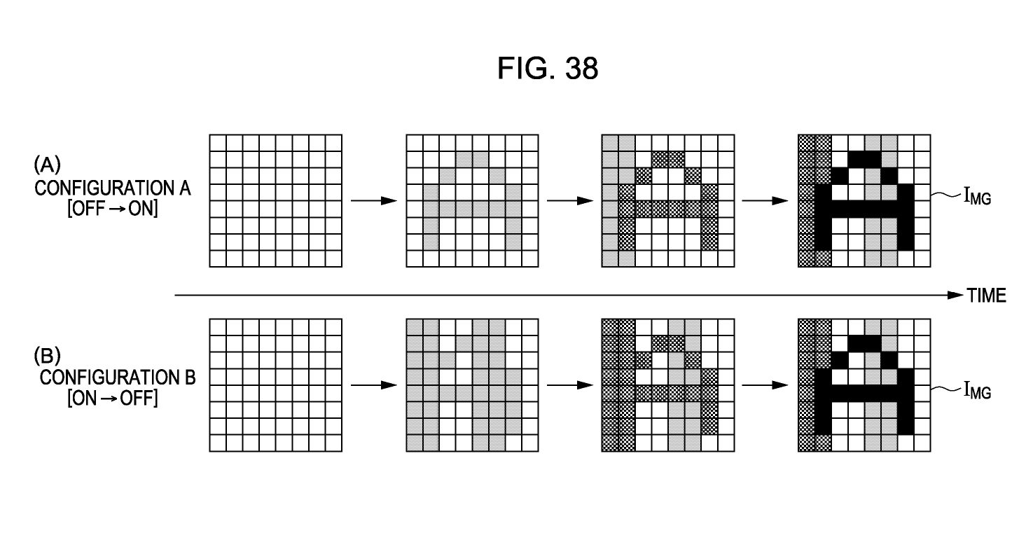

FIG. 38 is a schematic diagram of a state in which the display image of the display unit 20 is changed with time from the start point to the end point of the operation period T_{DRV}. A part (A) of FIG. 38 corresponds to configuration A and a part (B) of FIG. 38 corresponds to configuration B. In FIG. 38, the case of displaying an image I_{MG} including four kinds of gradations (white, black, and two kinds of middle tones) is considered, the image I_{MG} is an image in which a black character “A” is arranged in a background including white and a middle tone.

As shown in the part (B) of FIG. 38, in configuration B, the driving transistor T_{DR} of each pixel circuit P_{IX} in which gradations (black and a middle tone) other than white are designated is concurrently changed to the on state at the start point of the operation period T_{DRV} such that the gradation of the electrophoretic element 40 begins to transition to the black side and the driving transistor T_{DR} is changed from the on state to the off state at a time according to the designated gradation of each pixel circuit P_{IX} in the operation period T_{DRV} such that the change in the gradation of the electrophoretic element 40 is stopped. Accordingly, the black character “A” of the image I_{MG} is first recognized by the user in a step just before the end point of the operation period T_{DRV}.

In contrast, as shown in the part (A) of FIG. 38, in configuration A, the driving transistor T_{DR} of each pixel circuit P_{IX} is set to the off state at the start point of the operation period T_{DRV} and the driving transistor T_{DR} is changed from the off state to the on state at a time according to the designated gradation of each pixel circuit P_{IX} such that the gradation of the electrophoretic element 40 begins to transition to the black side. That is, as the designated gradation of each pixel circuit P_{IX} is close to black, the gradation of the electrophoretic element 40 begins to transition to black from an early time within the operation period T_{DRV}. Accordingly, the black character “A” is recognized by the user from the early time of the operation period T_{DRV}. That is, according to configuration A, it is possible to shorten a time when the user actually recognizes an image (in particular, a character) from the start point of the operation period T_{DRV}, as compared to configuration B.

### 2. Modified Example 2

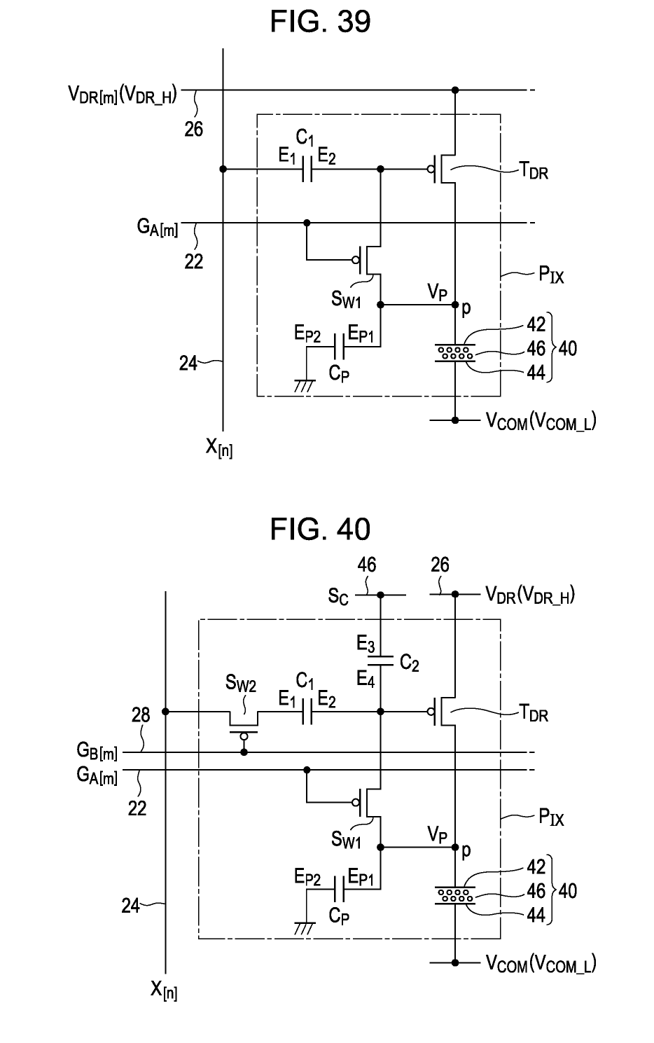

The conductive type of each transistor configuring the pixel circuit P_{IX} is arbitrarily changed. For example, the configuration of FIG. 39 in which each transistor (T_{DR}, S_{W1}) of the pixel circuit P_{IX} of the first embodiment (FIG. 2) is changed to a P channel type or the configuration of FIG. 40 in which each transistor (T_{DR}. S_{W1}, S_{W2}) of the pixel circuit P_{IX} of the fifth embodiment (FIG. 22) is changed to a P channel type may be employed. In the configuration of FIG. 39 or 40, the level of the voltage is reversed as compared to the configuration of FIG. 2 or FIG. 22. For example, in the operation period T_{DRV}, the common potential V_{COM} of the counter electrode 44 is set to the low-level potential V_{COM}_{_{—}}_{L} and the driving potential V_{DR[m]} (V_{DR}) of the driving potential line 26 is set to the high-level potential V_{DR}_{_{—}}_{H}. However, since the essential operation is equal to that of the above embodiments, the description of the operation of the case of employing the pixel circuit P_{IX} of FIG. 39 or FIG. 40 will be omitted. Although the pixel circuit P_{IX} in which different conductive types of transistors are mixed may be employed, from the viewpoint that the process of manufacturing the pixel circuit P_{IX} is simplified, the configuration in which the conductive type of each transistor within the pixel circuit P_{IX} is communalized is especially suitable as in the above embodiments.

The material, the structure or the manufacturing method of each transistor (T_{DR}, S_{W2}, S_{W2}) of the pixel circuit P_{IX} is arbitrarily changed. For example, as the material of a semiconductor layer of each transistor, an amorphous semiconductor (amorphous silicon), an oxide semiconductor, an organic semiconductor, or a polycrystalline semiconductor (for example, high-temperature polysilicon or low-temperature polysilicon) is arbitrarily employed.

### 3. Modified Example 3

In the above-described embodiments, the configuration (the first embodiment, the second embodiment, the third embodiment, and the fourth embodiment) in which the pixel circuit P_{IX} includes two transistors (T_{DR}, S_{W1}) and the configuration (the fifth embodiment and the sixth embodiment) in which the pixel circuit P_{IX} includes three transistors (T_{DR}, S_{W2}, S_{W2}) are described. As the configuration for setting the potential V_{G} of the gate of the driving transistor T_{DR} in the compensation preparation period Q_{A} as the initial compensation value V_{INI}, the configuration (the first embodiment, the fourth embodiment and the sixth embodiment) of using the movement of the charges of the additional capacitive element C_{P} accumulated in the initialization period T_{RST} and the configuration (the second embodiment, the third embodiment and the fifth embodiment) of using the difference between the increase amount δ_{L}_{_{—}}_{H} and the decrease amount δ_{H}_{_{—}}_{L} of the potential V_{G} are described. With respect to the configuration in which the potential V_{G} of the gate of the driving transistor T_{DR} is increased in the initialization period T_{RST}, the configuration (the first embodiment, the second embodiment and the fourth embodiment) of using the instruction signal X_{[n]} and the configuration (the third embodiment, the fifth embodiment and the sixth embodiment) of using the capacitive potential S_{C} are described. As the configuration in which the voltage V_{GS} between the gate and the source of the driving transistor T_{DR} is changed with time in the operation period T_{DRV}, the configuration (the first embodiment and the second embodiment) of setting the instruction signal X_{[n]} to the potential W(t), the configuration (the third embodiment, the fifth embodiment and the sixth embodiment) of setting the capacitive potential S_{C} to the potential W(t), and the configuration (the fourth embodiment) of setting the driving potential V_{DR} to the potential W(t) are described. A combination of the above-described elements (the configuration of setting the number of transistors of the pixel circuit P_{IX} and the initial compensation value V_{INI}, the configuration of increasing the potential V_{G} in the initialization period T_{RST}, and the configuration of changing the voltage V_{GS}) is arbitrary and is not limited to the above-described embodiments and modifications may be appropriately made.

### 4. Modified Example 4

Although the instruction signal X_{[n]} is set to the gradation potential V_{D[m,n]} before the start of the compensation execution period Q_{B} in the first embodiment to the fourth embodiment, the start point of the writing operation is appropriately changed. For example, a configuration of setting the instruction signal X_{[n]} to the gradation potential V_{D[m,n]} after the end point of the compensation preparation period Q_{A} may be employed. However, a configuration in which the potential of the electrode E₁ of the capacitive element C₁ is set to the gradation potential V_{D[m,n]} at the end point of the compensation execution period Q_{B} in which the potential V_{G} of the gate of the driving transistor T_{DR} is set to the potential V_{G}_{_{—}}_{TH} according to the threshold voltage V_{TH} is suitable.

### 5. Modified Example 5

Although the potential W(t) is controlled to a ramp waveform (that is, a linearly monotonically increased or monotonically decreased waveform) in the above embodiments, the waveform of the potential W(t) is arbitrary. For example, although the potential W(t) is linearly changed in the above-described embodiment, a configuration in which the potential W(t) is curvedly changed may be employed. Although the potential W(t) is monotonically increased (in the fourth embodiment, monotonically decreased) within the operation period T_{DRV} in the above-described embodiment, a configuration in which the potential W(t) is increased or decreased within the operation period T_{DRV}. More specifically, a triangular wave which is linearly increased (decreased) from the start point of the operation period T_{DRV} and is linearly decreased (increased) from an intermediate point in time or a sine wave which is curvedly changed within the operation period T_{DRV} may be used as the potential W(t).

### 6. Modified Example 6

Although the invention is applied to the pixel circuit P_{IX} for driving the electro-optical element (electrophoretic element 40) in the above-described embodiments, the use of the electronic circuit according to the invention is not limited to driving of the electro-optical element. The pixel circuit P_{IX} of the above-described embodiment generates a voltage signal according to the level of the gradation potential V_{D[m,n]} and the potential W(t) at the circuit point p. Accordingly, an electronic circuit which employs the configuration of the pixel circuit P_{IX} of the above-described embodiments (which does not include the electrophoretic element 40) may be used as a comparison circuit for comparing a first potential (for example, the gradation potential V_{D[m,n]} and a second potential (for example, the potential W(t)). A load (driving load) driven by the comparison circuit is not limited to the electro-optical element. Although the potential W(t) is changed with time in order to realize an operation (pulse width modulation) for variably controlling a time for applying the forward bias to the electrophoretic element 40 according to the gradation potential V_{D[m,n]} in the above-described embodiment, the potential W(t) does not need to be changed with time under the simple configuration for generating the signal according to the result of comparing a plurality of potential.

The pixel circuit P_{IX} of each of the above embodiments is an example of an electronic circuit for compensating for the threshold voltage V_{TH} of the driving transistor T_{DR} (that is, a circuit for setting the voltage V_{GS} between the gate and the source of the driving transistor T_{DR} according to its threshold voltage V_{TH}). As can be understood from the above description, in the invention, the comparison circuit for comparing the plurality of potentials, which is included as an electronic circuit for compensating for the threshold voltage V_{TH} of the driving transistor T_{DR}, is described as a suitable embodiment of the electronic circuit of the invention. The pixel circuit P_{IX} of each of the above embodiments is a detailed example in which the electronic circuit (comparison circuit) of the invention is used in driving of the electrophoretic element 40.

### 7. Modified Example 7

The relationship between the voltage applied to the electrophoretic element 40 and the gradation is not limited to the above embodiments. For example, contrary to the example of FIG. 3, in the case of using the electrophoretic element 40 using white charged particles 462W charged with a negative polarity and black charged particles 462B charged with a positive polarity, the display gradation of the electrophoretic element 40 transitions to the white side by the application of the forward bias in the operation period T_{DRV} and transitions to the black side by the application of the reverse bias in the initialization period T_{RST}. The positions of the pixel electrode 42 and the counter electrode 44 (observation side/rear surface side) are also changed. For example, if the counter electrode 44 is mounted on the rear surface side and the pixel electrode 42 is mounted on the front surface side in the example of FIG. 3, a configuration for transitioning the display gradation of the electrophoretic element 40 to the white side by the application of the forward bias is realized.

The configuration of the electrophoretic element 40 is also appropriately changed. For example, a configuration in which the white charged particles 462W are dispersed in the black dispersion medium 464 or a configuration in which black charged particles 462B are dispersed in the white dispersion medium 464 may be employed (1 particle system). The color of the charged particles 462 or the dispersion medium 464 configuring the electrophoretic element 40 is not limited to white and black and is arbitrarily changed. The electrophoretic element 40 in which at least three kinds of particles (for example, one kind of particle is not charged) corresponding to different display colors are dispersed may be employed.

An object driven by the pixel circuit P_{IX} of each of the above embodiments is not limited to the electrophoretic element 40. For example, the invention is applicable to driving of an arbitrary electro-optical element such as a liquid crystal element, a light emitting element (for example, an organic EL element or a Light Emitting Diode (LED)), a field electron emission element (Field-Emission (FE) element), a surface electrical connection electron emission element (Surface electrical connection Electron emitter (SE) element), a ballistic electron emission element (Ballistic electron Emitting (BS) element), or a light receiving element. That is, the electro-optical element is included as a driven element for converting one into the other of an electrical operation (voltage application or current supply) and an optical operation (gradation change or light emission). From the viewpoint that the error of the characteristics of the driving transistor T_{DR} is effectively compensated for, the invention is especially suitable when an electro-optical element with high resistance, such as an electrophoretic element 40 or a liquid crystal element, is driven.

### I: Application

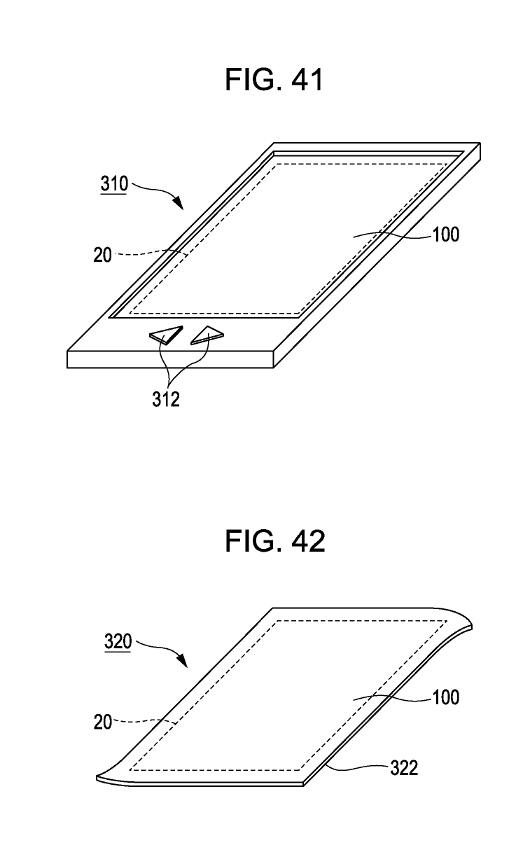

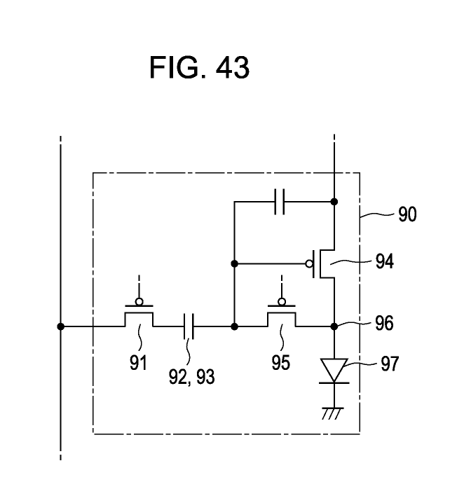

An electronic apparatus in which the invention is applied will now be described. The appearance of an electronic apparatus which employs the electro-optical device 100 of each of the above embodiments as a display device is shown in FIGS. 41 and 42.

FIG. 41 is a perspective view of a portable information terminal (electronic book) 310 using the electro-optical device 100. As shown in FIG. 41, the information terminal 310 includes an operation unit 312 operated by a user and an electro-optical device 100 for displaying an image on a display unit 20. If the operation unit 312 is operated, a display image of the display unit 20 is changed. FIG. 42 is a perspective view of an electronic paper 320 using an electro-optical device 100. As shown in FIG. 42, the electronic paper 320 includes an electro-optical device 100 formed on a surface of a flexible substrate (sheet) 322.

The electronic apparatus of the invention is not limited to the above embodiments. For example, the electronic apparatus (electro-optical device) of the invention may be employed in various electronic apparatuses, such as a mobile telephone, a watch (wristwatch), a portable sound reproduction device, an electronic organizer, or a display device equipped with a touch panel.

What is claimed is:

1. An electronic apparatus comprising an electronic circuit and a driving circuit,
wherein the electronic circuit includes:
a driving transistor including a first terminal connected to a driving potential line to which a driving potential is supplied, a second terminal connected to a circuit point, and a control terminal for controlling a connection state between both terminals;
an additional capacitive element connected to the circuit point; and
a first switch which controls a connection between the circuit point and the control terminal,
wherein the driving circuit controls the first switch to an off state and changes the potential of the control terminal such that the driving transistor transitions to an on state, in a first period in which the driving potential is set to a first potential,
controls the first switch to the on state so as to set the potential of the control terminal to an initial compensation value, in a second period after the elapse of the first period, and
controls the first switch to the on state and changes the driving potential from the first potential to a second potential such that the driving transistor transitions to the on state, in a third period after the elapse of the second period.

2. The electronic apparatus according to claim 1, wherein the driving circuit changes the potential of the control terminal in an opposite direction of the change in the first period before the start of the second period and controls the first switch to the on state in the second period so as to set the potential of the control terminal to the initial compensation value.

3. The electronic apparatus according to claim 1, wherein the driving circuit changes the potential of the control terminal in an opposite direction of the change in the first period so as to set the potential of the control terminal to the initial compensation value, after the first switch is controlled to the on state, in the second period.

4. The electronic apparatus according to claim 1, wherein the electronic circuit includes a first capacitive element including a first electrode and a second electrode,
the second electrode is connected to the control terminal, and
the driving circuit supplies a signal potential to the first electrode within the third period or after the elapse of the third period, and variably sets a voltage between the control terminal and the first terminal in a fourth period after the elapse of the third period.

5. The electronic apparatus according to claim 4, wherein the driving circuit variably sets the potential of the first electrode in the fourth period.

6. The electronic apparatus according to claim 4, wherein the electronic circuit includes a second capacitive element including a third electrode and a fourth electrode,
the fourth electrode is connected to the control terminal, and
the driving circuit variably sets the potential of the third electrode in the fourth period.

7. The electronic apparatus according to claim 4, wherein the driving circuit variably sets the driving potential of the driving potential line in the fourth period.

8. The electronic apparatus according to claim 4, wherein the first electrode of the first capacitive element is directly connected to a signal line to which the signal potential is supplied.

9. The electronic apparatus according to claim 4, wherein the electronic circuit includes a second switch which controls electrical connection between the first electrode of the first capacitive element and a signal line to which the signal potential is supplied.

10. A method of driving an electronic apparatus including a driving transistor having a first terminal connected to a driving potential line to which a driving potential is supplied, a second terminal connected to a circuit point and a control terminal for controlling a connection state between both terminals, an additional capacitive element connected to the circuit point, and a first switch which controls a connection between the circuit point and the control terminal, the method comprising:
controlling the first switch to an off state and changing the potential of the control terminal such that the driving transistor transitions to an on state, in a first period in which the driving potential is set to a first potential;
controlling the first switch to the on state so as to set the potential of the control terminal to an initial compensation value, in a second period after the elapse of the first period; and
controlling the first switch to the on state and changing the driving potential from the first potential to a second potential such that the driving transistor transitions to the on state, in a third period after the elapse of the second period.
